(19) United States
(12) Patent Application Publication
(10) Pub. No.: US 2021/0357060 A1
(43) Pub. Date: Nov. 18, 2021

(54) DISPLAY DEVICE

(71) Applicant: Samsung Display Co., Ltd., Yongin-Si, Gyeonggi-do (KR)

(72) Inventors: Byoung Yong KIM, Seoul (KR); Seung Yong SONG, Suwon-si (KR); Seung Soo RYU, Hwaseong-si (KR); Dae Geun LEE, Hwaseong-si (KR); Sang Duk LEE, Yongin-si (KR)

(21) Appl. No.: 17/278,244

(22) PCT Filed: Jul. 8, 2019
(86) PCT No.: PCT/KR2019/008349

§ 371 Date: Mar. 19, 2021

(30) Foreign Application Priority Data
Sep. 21, 2018 (KR) 10-2018-0114433

(51) Int. Cl. G06F 3/041; H01L 27/32; H01L 51/52; G06F 3/044

(52) U.S. Cl. CPC G06F 3/0412; G06F 3/0446; H01L 51/524; H01L 27/323

(57) ABSTRACT

A display device includes: a display region; a non-display region surrounding the display region; a first substrate; a second substrate on the first substrate, and including a first surface facing the first substrate, and a second surface opposite to the first surface; a touch electrode on the second surface of the second substrate at the display region; a touch pad terminal on the second surface of the second substrate at the non-display region, and electrically connected to the touch electrode; and a sealing member interposed between the first substrate and the second substrate, and connecting the first substrate and the second substrate to each other. The sealing member is at the non-display region, and the touch pad terminal is located more inward than the sealing member.

### CROSS-REFERENCE TO RELATED APPLICATIONS

This application is a U.S. National Phase Patent Application of International Application No. PCT/KR2019/008349, filed on Jul. 8, 2019, which claims priority to Korean Patent Application No. 10-2018-0114433, filed on Sep. 21, 2018, the entire content of all of which is hereby incorporated by reference herein.

### BACKGROUND

### 1. Field

Aspects of embodiments of the present disclosure relate to a display device.

### 2. Description of Related Art

A display device is a device for displaying a moving image and/or a still image. The display device may be used as a display screen of various suitable products, for example, such as a television, a laptop, a monitor, a billboard, an Internet of Things device, and the like, as well as for various suitable portable electronic devices, for example, such as a mobile phone, a smart phone, a tablet PC (personal computer), a smart watch, a watch phone, a mobile communication terminal, an electronic notebook, an e-book reader, a portable multimedia player (PMP), a navigation device, an ultra-mobile PC (UMPC), and the like.

The display device may be, for example, an organic light-emitting display device. Image displays of display devices such as the organic light-emitting display device are due to light transmission. In particular, the transmittance of light may affect the display quality, for example, such as the brightness of the display device. Therefore, components constituting the display device may at least partially include a transparent member, for example, such as a glass member.

The organic light-emitting display device may include a base substrate as the glass member, a lower substrate, and an upper substrate as an encapsulation substrate. Normally, laser sealing may be used to irradiate a laser with a frit interposed between the upper and lower substrates in order to bond the glass members.

A touch screen may be directly formed on the upper substrate. Normally, a display device to which this method is applied is referred to as a touch screen panel integrated display device. The touch screen may include a plurality of touch signal pads on one side thereof, and the touch signal pads may be ultrasonically bonded to an external device, for example, such as to a touch flexible printed circuit board.

However, when the laser sealing described above is performed on the lower substrate and the upper substrate on which the touch screen is formed, the laser sealing may not be smoothly performed due to a touch signal pad that is formed on the upper substrate.

The above information disclosed in this Background section is for enhancement of understanding of the background of the present disclosure, and therefore, it may contain information that does not constitute prior art.

### SUMMARY

One or more embodiments of the present disclosure are directed to a display device including a touch signal pad that is disposed so as to not overlap with a sealing region to improve bonding properties between an upper substrate and a lower substrate of the display device.

However, the aspects and features of the present disclosure are not limited to those discussed above, and other aspects and features will be clearly understood by those skilled in the art from the following description.

According to an embodiment of the present disclosure, a display device includes: a display region; a non-display region surrounding the display region; a first substrate; a second substrate on the first substrate, and including a first surface facing the first substrate, and a second surface opposite to the first surface; a touch electrode on the second surface of the second substrate at the display region; a touch pad terminal on the second surface of the second substrate at the non-display region, and electrically connected to the touch electrode; and a sealing member interposed between the first substrate and the second substrate, and connecting the first substrate and the second substrate to each other. The sealing member is at the non-display region, and the touch pad terminal is located more inward than the sealing member.

In an embodiment, the touch pad terminal may not overlap with the sealing member.

In an embodiment, the display device may further include a display element, the first substrate may include a first surface facing the second substrate, and a second surface opposite to the first surface of the first substrate, and the display element may be located on the first surface of the first substrate.

In an embodiment, the display element may include an anode, a cathode, and an organic emission layer between the anode and the cathode.

In an embodiment, the display element may be sealed by the first substrate, the second substrate, and the sealing member.

In an embodiment, the second substrate may include glass or quartz.

In an embodiment, the touch electrode may be located directly on the second surface of the second substrate.

In an embodiment, the sealing member may include an optically transparent frit.

In an embodiment, the touch electrode may include a transparent electrode layer including a transparent conductive oxide.

In an embodiment, the touch pad terminal may include a first conductive layer including a transparent conductive oxide, and a second conductive layer on the first conductive layer and including an opaque metal.

In an embodiment, the transparent electrode layer and the first conductive layer may include the same material as each other.

In an embodiment, the second conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb.

In an embodiment, the display device may further include a circuit board attached onto the second surface of the second substrate.

In an embodiment, the circuit board may include a lead terminal connected to the touch pad terminal.

In an embodiment, the touch pad terminal and the lead terminal may be ultrasonically bonded to each other.

In an embodiment, the first substrate may extend from one end of the second substrate to the outside of the second substrate.

In an embodiment, the circuit board may be bent to surround a region of the first substrate extending from one end of the second substrate in a plan view, and one end of the circuit board may be located below the second surface of the first substrate.

According to an embodiment of the present disclosure, a display device includes: a display region; a non-display region surrounding the display region; a display substrate; an encapsulation substrate on the display substrate, and including a first surface facing the display substrate, and a second surface opposite to the first surface; a touch electrode on the second surface of the encapsulation substrate at the display region; a touch pad terminal on the second surface of the encapsulation substrate at the non-display region, and electrically connected to the touch electrode; a display element on the display region of the display substrate, and sealed by the display substrate, the sealing member, and the encapsulation substrate; and a touch element on the encapsulation substrate, and overlapping with the display region of the display substrate. The touch pad terminal overlaps with a portion of a sealing region of the display substrate, and includes a first pad conductive layer, and a second pad conductive layer on the first pad conductive layer, the second pad conductive layer including an opaque metal.

In an embodiment, the touch electrode may include a transparent electrode layer including a transparent conductive oxide.

In an embodiment, the transparent electrode layer and the first pad conductive layer may include the same material as each other.

In an embodiment, the second pad conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb.

In an embodiment, the display device may further include a display element, the display substrate may include a first surface facing the encapsulation substrate, and a second surface opposite to the first surface of the first substrate, and the display element may be located on the first surface of the display substrate.

In an embodiment, the display element may include an anode, a cathode, and an organic emission layer between the anode and the cathode.

In an embodiment, the display element may be sealed by the display substrate, the encapsulation substrate, and the sealing member.

In an embodiment, the encapsulation substrate may include glass or quartz, and the touch electrode may be located directly on the second surface of the encapsulation substrate.

In an embodiment, the sealing member may include an optically transparent frit.

In an embodiment, the display device may further include a touch circuit board attached onto the second surface of the encapsulation substrate, and the touch circuit board may include a lead terminal connected to the touch pad terminal.

In an embodiment, the touch pad terminal and the lead terminal may be ultrasonically bonded to each other.

In an embodiment, the display substrate may extend from one end of the encapsulation substrate to the outside of the encapsulation substrate in a plan view.

In an embodiment, the touch circuit board may be bent to surround a region of the display substrate extending from the one end of the encapsulation substrate in the plan view, and one end of the touch circuit board may be located below the second surface of the display substrate.

A display device according to one or more embodiments of the present disclosure may improve bonding properties between an upper substrate and a lower substrate thereof by disposing a touch signal pad so as to not overlap with a sealing region.

However, the aspects and features of the present disclosure are not limited to those described above, and other aspects and features of the present disclosure are included in the following description.

### BRIEF DESCRIPTION OF THE DRAWINGS

The above and other aspects and features of the present disclosure will become more apparent to those skilled in the art from the following detailed description of the example embodiments with reference to the accompanying drawings.

FIG. 1 is a planar layout view of a display device according to an embodiment.

FIG. 2 is a cross-sectional view of the display device of FIG. 1.

FIG. 3 is a planar layout view of an upper substrate according to an embodiment.

FIG. 4 is a cross-sectional view of a touch member of a sensing region according to an embodiment.

FIG. 5 is a cross-sectional view of a touch member of a sensing region according to a modified example.

FIG. 6 is a planar layout view of a touch signal pad terminal according to an embodiment.

FIG. 7 is a cross-sectional view taken along the line VII-VII′ of FIG. 6.

FIG. 8 is a cross-sectional view taken along the line VIII-VIII′ and the line IX-IX′ of FIG. 6.

FIG. 9 is a perspective view illustrating a process of sealing an upper substrate and a lower substrate according to an embodiment.

FIG. 10 is a planar layout view of a touch signal pad terminal according to another embodiment.

FIG. 11 is a cross-sectional view taken along the line XI-XI′ of FIG. 10.

FIG. 12 is a cross-sectional view taken along the line XII-XII′ and the line XIII-XIII′ of FIG. 10.

FIG. 13 is a planar layout view of a touch signal pad terminal according to another embodiment.

FIG. 14 is a cross-sectional view taken along line the XIV-XIV′ of FIG. 13.

FIG. 15 is a cross-sectional view taken along the line XV-XV′ and the line XVI-XVI′ of FIG. 13.

FIG. 16 is a planar layout view of an upper substrate according to another embodiment.

FIG. 17 is a cross-sectional view of a touch member of a sensing region according to another embodiment.

FIG. 18 is a planar layout view of a touch signal pad terminal according to another embodiment.

FIG. 19 is a cross-sectional view taken along the line XIX-XIX′ of FIG. 18.

FIG. 20 is a cross-sectional view taken along the line XX-XX and the line XXI-XXI′ of FIG. 18.

FIG. 21 is a cross-sectional view of a display device according to another embodiment.

FIG. 22 is a planar layout view of an upper substrate according to another embodiment.

FIG. 23 is a flowchart illustrating a method of manufacturing a display device according to an embodiment.

FIGS. 24-26 are perspective views illustrating a process of forming a touch signal pad terminal.

### DETAILED DESCRIPTION

Hereinafter, example embodiments of the present disclosure, and methods for achieving them, will be described in more detail with reference to the accompanying drawings. However, the present disclosure is not limited to the embodiments disclosed below, and may be implemented in various different forms. In other words, the present disclosure is defined by the scope of the claims, and their equivalents.

It will be understood that when an element or layer is referred to as being “on,” “connected to,” or “coupled to” another element or layer, it can be directly on, connected to, or coupled to the other element or layer, or one or more intervening elements or layers may be present. On the other hand, when an element or layer is referred to as being “directly connected to,” “directly on,” or “directly above” another element or layer, no intervening elements or layers may be present therebetween.

Throughout the specification, the same reference symbols are used for the same or substantially the same (or similar) parts.

Hereinafter, embodiments of the present disclosure will be described in more detail with reference to the drawings.

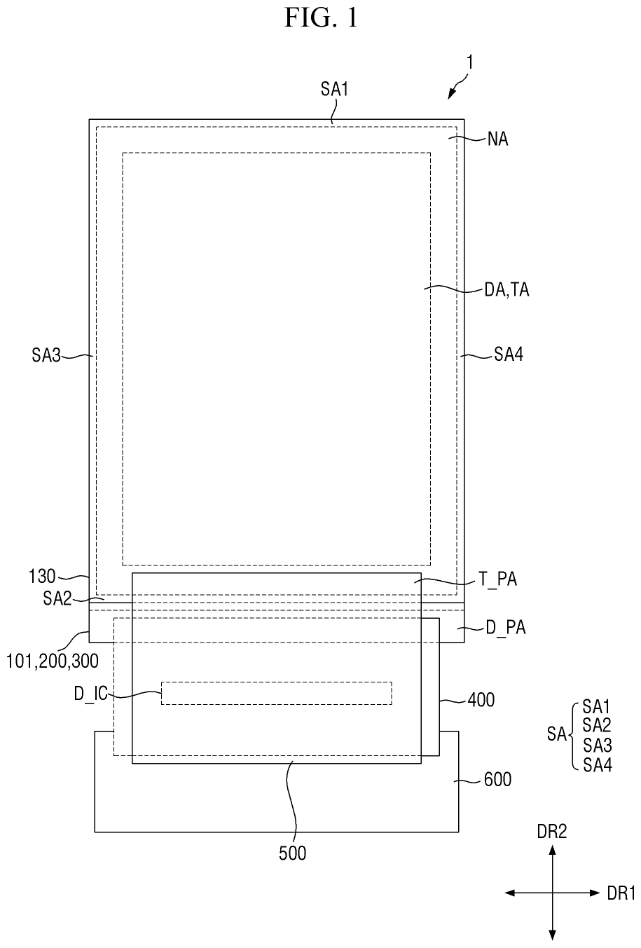

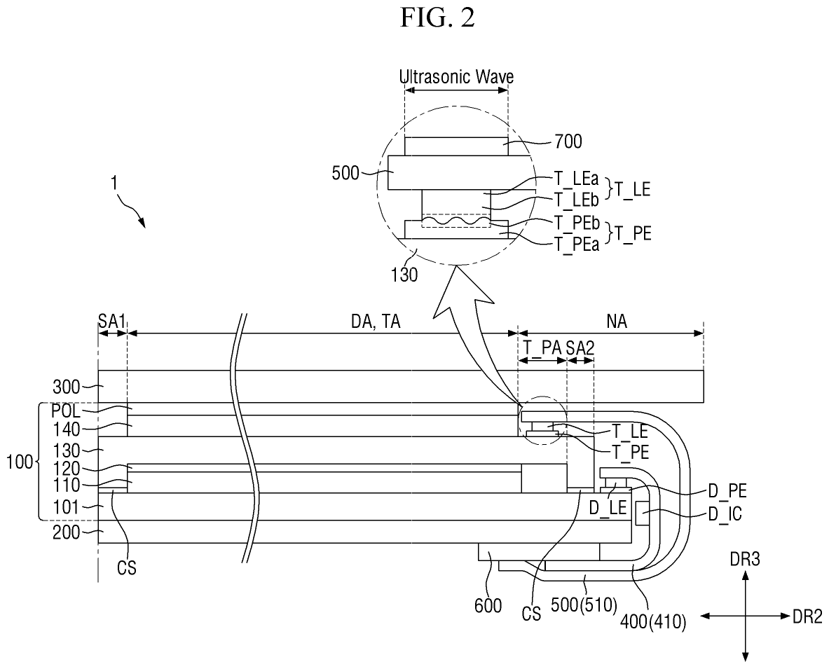

FIG. 1 is a planar layout view of a display device according to an embodiment, and FIG. 2 is a cross-sectional view of the display device of FIG. 1.

Referring to FIGS. 1 and 2, a display device 1 may include a display panel 100 for displaying an image, a panel lower sheet 200 disposed below the display panel 100, a window 300 disposed on the display panel 100, a display printed circuit board 400 attached to a display pad region D_PA of the display panel 100, and a touch printed circuit board 500 attached to a touch pad region T_PA of the display panel 100.

The display panel 100 may include a lower substrate 101, an upper substrate 130, various suitable elements disposed on the lower substrate 101, and various suitable elements disposed on the upper substrate 130.

The lower substrate 101 may have a rectangular shape of which a corner has a right angle on a plane (e.g., in a plan view or in a view from a direction that is perpendicular to or substantially perpendicular to a top surface of the relevant element or layer). The lower substrate 101 may have a short side and a long side on the plane. The long side of the lower substrate 101 may be a side extending in a second direction DR2. The short side of the lower substrate 101 may be a side extending in a first direction DR1 crossing the second direction DR2. The lower substrate 101 may be formed to extend further in one direction from one side (e.g., from one end) of the upper substrate 130. For example, the lower substrate 101 may be formed to extend further at one lower end thereof from one end of the upper substrate 130 in the second direction DR2.

The upper substrate 130 may have the same or substantially the same planar shape as that of the lower substrate 101. In other words, the upper substrate 130 may have a rectangular shape of which a corner has a right angle on a plane. The upper substrate 130 may have a long side and a short side on the plane. The long side of the upper substrate 130 may be a side extending in the second direction DR2. The short side of the upper substrate 130 may be a side extending in the first direction DR1. The upper substrate 130 may be disposed to be indented inward in one direction from one side (e.g., one end) of the lower substrate 101. For example, one side or one end of the upper substrate 130 may retreat inward from one end of the lower substrate 101 in the second direction DR2. The display pad region D_PA, which will be described in more detail below, may be positioned in the extended region of the lower substrate 101.

Except for a region in which the lower substrate 101 protrudes further than the upper substrate 130, side surfaces of the lower substrate 101 and the upper substrate 130 may be aligned with each other in a thickness direction (e.g., in a third direction DR3). However, the present disclosure is not limited thereto, and the side surfaces of the lower substrate 101 and the upper substrate 130 may not be aligned with each other in the thickness direction including the protruding region, and may be formed so that the side surfaces of the lower substrate 101 protrude further outward than the side surfaces of the upper substrate 130.

A planar profile of the display panel 100 may be determined according to the planar profiles of the lower substrate 101 and the upper substrate 130. In an embodiment, the display panel 100 may have the same or substantially the same planar size as that of the lower substrate 101, and may have a rectangular shape according to the planar shape of the lower substrate 101. The display panel 100 may be formed to include a region in which the upper substrate 130 and the lower substrate 101 overlap with each other on the plane, and a region in which the lower substrate 101 protrudes further outward than the upper substrate 130, or in other words, a region in which the lower substrate 101 further extends in the second direction DR2 than the upper substrate 130.

The lower substrate 101 may include a display region DA, and a non-display region NA disposed around (e.g., to surround around a periphery of) the display region DA. The non-display region NA of the lower substrate 101 may include a sealing region SA, and the display pad region D_PA.

The display region DA may have a rectangular shape of which a corner thereof has a right angle on a plane, or a rectangular shape with rounded corners on the plane. The display region DA may have a short side and a long side. The short side of the display region DA may be a side extending in the first direction DR1. The long side of the display region DA may be a side extending in the second direction DR2. However, the planar shape of the display region DA is not limited to the rectangular shape, and the display region DA may have any suitable planar shape, for example, such as a circular shape, an elliptical shape, or other various suitable shapes.

The non-display region NA may be disposed around (e.g., to surround around a periphery of) the display region DA. The non-display region NA may be disposed to be adjacent to both short sides and both long sides of the display region DA. In this case, the non-display region NA may surround (e.g., around a periphery of) all sides of the display region DA to form an edge of the display region DA. However, the present disclosure is not limited thereto, and the non-display region NA may be disposed to be adjacent to only both short sides or only both long sides of the display region DA.

The sealing region SA may be disposed at (e.g., in or on) a region in which the upper substrate 130 and the lower substrate 101 overlap with each other in the thickness direction. The sealing region SA may be positioned along an edge portion or an edge region of the upper substrate 130. The sealing region SA may have a rectangular frame shape that is continuously disposed along the edge region of the upper substrate 130.

The sealing region SA may include first to fourth sealing regions SA1 to SA4. The first sealing region SA1 may be disposed to be adjacent to an upper short side of the display panel 100. In other words, the first sealing region SA1 may be disposed to be adjacent to an upper short side or an upper end portion of the upper substrate 130 and the lower substrate 101.

The second sealing region SA2 may be disposed to be adjacent to a lower short side of the display panel 100. In other words, the second sealing region SA2 may be disposed to be adjacent to a lower short side or a lower end portion of the upper substrate 130 and the lower substrate 101.

The third sealing region SA3 may be disposed to be adjacent to a left long side of the display panel 100. In other words, the third sealing region SA3 may be disposed to be adjacent to a left long side or a left end portion of the upper substrate 130 and the lower substrate 101.

The fourth sealing region SA4 may be disposed to be adjacent to a right long side of the display panel 100. In other words, the fourth sealing region SA4 may be disposed to be adjacent to a right long side or a right end portion of the upper substrate 130 and the lower substrate 101.

The sealing regions SA1 to SA4 may be regions at (e.g., in or on) which a frit is interposed between the lower substrate 101 and the upper substrate 130 to bond (e.g., to attach) the upper substrate 130 and the lower substrate 101 to each other. This will be described in more detail below.

As described above, the display pad region D_PA may be positioned on the region of the lower substrate 101 that protrudes further outward than the upper substrate 130. In other words, the display pad region D_PA is a region that does not overlap with the upper substrate 130, and may be disposed to be adjacent to the lower short side or the lower end portion of the lower substrate 101.

The upper substrate 130 may include a sensing region TA, and a non-display region NA disposed around (e.g., to surround around a periphery of) the sensing region TA.

As described in more detail below, the sensing region TA of the upper substrate 130 may be a region at (e.g., in or on) which a plurality of touch electrodes 151, 161, 162, and 163 of the upper substrate 130 are disposed. The sensing region TA may have the same or substantially the same shape as that of the display region DA on the plane. In other words, the sensing region TA has a rectangular shape having long sides and short sides, and may overlap with (e.g., may entirely or substantially overlap with) the display region DA in the thickness direction. However, the present disclosure is not limited thereto, and the sensing region TA may have a smaller size on a plane than that of the display region DA of the display panel 100, and may partially overlap with the display region DA.

The non-display region NA of the upper substrate 130 may include the sealing region SA, and the touch pad region T_PA.

The sealing region SA of the upper substrate 130 refers to the same region as the sealing region SA of the lower substrate 150. In other words, the sealing region SA may be disposed at (e.g., in or on) a region in which the upper substrate 130 and the lower substrate 101 overlap with each other in the thickness direction. The sealing region SA may be positioned along the edge portion or the edge region of the upper substrate 130. The sealing region SA may have a rectangular frame shape that is continuously disposed along the edge region of the upper substrate 130.

The touch pad region T_PA may be disposed between the sensing region TA of the upper substrate 130 and the second sealing region SA2. The touch pad region T_PA may not overlap with the second sealing region SA2 of the display panel 100 in the thickness direction. As described in more detail below, a plurality of touch signal pad terminals T_PE may be disposed at (e.g., in or on) the touch pad region T_PA. The touch signal pad terminals T_PE may not overlap with the second sealing region SA2. Accordingly, a sealing failure between the upper substrate 130 and the lower substrate 101 may be improved (e.g., may be reduced). This will be described in more detail below.

As an example, an organic light-emitting display panel may be applied (e.g., may be used) as the display panel 100. In the following embodiment, it is described and illustrated that the organic light-emitting display panel is applied (e.g., is used) as the display panel 100, but the present disclosure is not limited thereto. For example, in other embodiments, other suitable kinds of display panels may be applied (e.g., may be used), such as a liquid crystal display (LCD), a quantum dot organic light-emitting display panel (QD-OLED), a quantum dot liquid crystal display (QD-LCD), a quantum nano light-emitting display panel (QNED), and/or a Micro LED display.

As shown in FIG. 1, the display printed circuit board 400 may be disposed on the display pad region D_PA of the display panel 100. The display printed circuit board 400 may be attached to the display pad region D_PA. One end of the display printed circuit board 400 may be attached to the display pad region D_PA.

The display printed circuit board 400 may include a first base substrate 410, a plurality of display signal lead terminals D_LE, and a data driving chip D_IC.

The first base substrate 410 may be a flexible substrate. In an embodiment, the first base substrate 410 may be made of a flexible material, for example, such as polyimide.

The plurality of display signal lead terminals D_LE may be directly connected to a plurality of display signal pad terminals D_PE of the display pad region D_PA. As described in more detail below, the display signal lead terminal D_LE may be ultrasonically bonded to the display pad terminal D_LE. The plurality of display signal lead terminals D_LE may be directly connected to the plurality of display signal pad terminals D_PE without any configuration or layer therebetween. The display signal pad terminal D_PE may be electrically connected to the display printed circuit board 400 by being connected to the display signal lead terminal D_LE. The ultrasonic bonding of the display signal pad terminal D_PE and the display signal lead terminal D_LE will be described in more detail in the description of the ultrasonic bonding between the touch signal pad terminal T_PE and the touch signal lead terminal T_LE.

The display signal lead terminal D_LE may be electrically connected to the data driving chip D_IC through a signal line. In the figures, a case in which a data driving integrated circuit is applied as the data driving chip D_IC, and connected to the display panel 100 through a flexible printed circuit board is illustrated for convenience. However, the present disclosure is not limited thereto, and the data driving integrated circuit may be implemented as a driving chip, and may be applied as a chip on glass (COG) mounted directly on the rigid display panel 100. When the display panel 100 is flexible, the data driving integrated circuit may be applied as a chip on plastic (COP) mounted directly on the flexible display panel 100. Hereinafter, a case in which the data driving integrated circuit is implemented as the data driving chip D_IC, and applied as a chip on film (COF) will be mainly described in more detail.

Similarly, the touch printed circuit board 500 may be disposed on the touch pad region T_PA of the display panel 100. The touch printed circuit board 500 may be attached to the touch pad region T_PA. One end of the touch printed circuit board 500 may be attached to the touch pad region T_PA.

The touch printed circuit board 500 may partially overlap with the display printed circuit board 400 in the thickness direction on a surface (e.g., on one surface) of the display panel 100. The touch printed circuit board 500 may overlap with the display pad region D_PA and the second sealing region SA2 in the thickness direction, and may be covered from above.

The touch printed circuit board 500 may include a second base substrate 510, and the plurality of touch signal lead terminals T_LE disposed on the second base substrate 510.

The second base substrate 510 may be a flexible substrate. In an embodiment, the second base substrate 510 may be made of a flexible material, for example, such as polyimide.

The plurality of touch signal lead terminals T_LE may be directly connected to the touch signal pad terminals T_PE of the touch pad region T_PA. As described in more detail below, the touch signal lead terminal T_LE may be ultrasonically bonded to the touch pad terminal T_LE. The plurality of touch signal lead terminals T_LE may be directly connected to the touch signal pad terminals T_PE without any configuration or layer therebetween. The touch signal pad terminal T_PE may be electrically connected to the touch printed circuit board 500 by being connected to the touch signal lead terminal T_LE. The ultrasonic bonding of the touch signal pad terminal T_PE and the touch signal lead terminal T_LE will be described in more detail below.

Other ends (e.g., opposite ends) of the display printed circuit board 400 and the touch printed circuit board 500 may be attached to a main circuit board 600. The display printed circuit board 400 may be bent to surround (e.g., around a periphery of) one side surface outside the one side surface of the lower substrate 101, and may be disposed on a lower surface (e.g., a rear surface) of the lower substrate 101. The touch printed circuit board 500 may be bent to surround (e.g., around a periphery of) one side surface of the upper substrate 130, the display printed circuit board 400, and one side surface of the lower substrate 101, and may be disposed on the lower surface of the lower substrate 101. The main circuit board 600 may be attached to a lower surface of the panel lower sheet 200, which will be described in more detail below.

The panel lower sheet 200 may be disposed under the display panel 100. The panel lower sheet 200 may include at least one functional layer. The functional layer may be a layer that performs a heat dissipation function, an electromagnetic wave shielding function, a grounding function, a buffering function, a strength reinforcing function, a supporting function, and/or a digitizing function. The functional layer may be a sheet layer made of a sheet, a film layer made of a film, a thin film layer, a coating layer, a panel, a plate, or the like. One functional layer may include a single layer, but may also include a plurality of stacked thin films or coating layers. The functional layer may be, for example, a supporting substrate, a heat dissipation layer, an electromagnetic wave shielding layer, a shock absorbing layer, a digitizer, or the like. The main circuit board 600 described above may be attached to the lower surface of the panel lower sheet 200, which will be described in more detail below.

The window 300 is disposed on the display panel 100. The window 300 is disposed on the display panel 100 to protect the display panel 100 while transmitting light emitted from the display panel 100. The window 300 may be made of glass or the like.

The window 300 may be disposed to overlap with the display panel 100 on a plane, and to cover an entire surface of the display panel 100. The window 300 may be larger than the display panel 100. For example, at (e.g., in or on) both short sides of the display device 1, the window 300 may protrude outward from the display panel 100. The window 300 may protrude from the display panel 100 even at (e.g., in or on) both long sides of the display device 1, but a protruding distance of the window 300 at the short sides may be larger than that of the window 300 at the long sides. In addition, the window 300 may further extend outward from the display printed circuit board 400 and the touch printed circuit board 500 attached to the display panel 100 while being bent to cover the display printed circuit board 400 and the touch printed circuit board 500.

As described above, the display panel 100 may include the lower substrate 101 and the upper substrate 130, and may further include a circuit driving layer 110, an organic light-emitting element layer 120, a touch electrode layer 140, and a polarizing layer POL.

The lower substrate 101 and the upper substrate 130 may be rigid substrates. The upper substrate 130 may be made of a suitable material, for example, such as glass or quartz. As shown in FIG. 2, the upper substrate 130 may mostly overlap with the lower substrate 101, except for the display pad region D_PA. In other words, the upper substrate 130 may be disposed from the first sealing region SA1 to the second sealing region SA2.

The upper substrate 130 may be bonded or sealed with (e.g., may be attached to) the lower substrate 101 at (e.g., in or on) the first sealing region SA1 and the second sealing region SA2. The bonding or sealing of the upper substrate 130 with the lower substrate 101 may be performed through a cell seal CS. A lower surface of the upper substrate 130 and an upper surface of the lower substrate 101 at (e.g., in or on) the corresponding region (e.g., the corresponding sealing region SA) may be bonded or sealed (e.g., may be attached) to each other through the cell seal CS. The bonding of the upper substrate 130 to the lower substrate 101 may be performed by a laser sealing process. The cell seal CS may bond the upper substrate 130 and the lower substrate 101 to each other, while a suitable material such as a frit is melted and then solidified again.

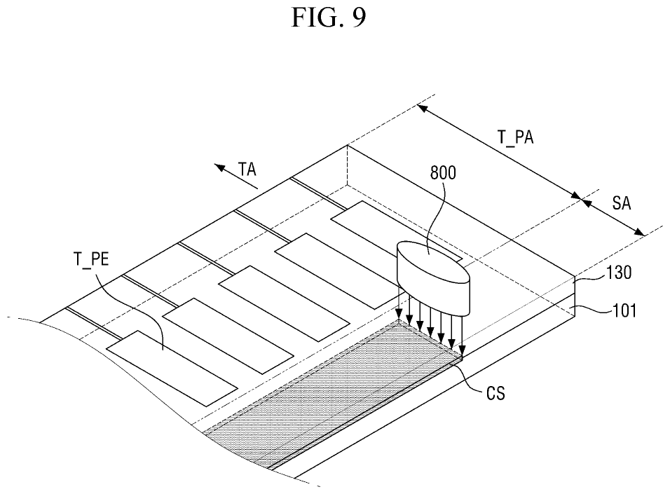

In more detail, the frit may be interposed between the lower substrate 101 and the upper substrate 130 at (e.g., in or on) the sealing region SA of the display panel 100. Thereafter, when the laser is irradiated to the sealing region SA through a laser sealing device 800 (e.g., see FIG. 9), the frit of the corresponding region may be melted. While the molten frit is solidified, the lower substrate 101 and the upper substrate 130 may be bonded or sealed to each other.

In the figures, the frit is illustrated as being interposed between the lower substrate 101 and the upper substrate 130 to perform the sealing process, but the present disclosure is not limited thereto. For example, in some embodiments, the lower substrate 101 and the upper substrate 130 may be directly coupled or bonded to each other without any configuration or layer therebetween. In other words, when the laser sealing device 800 irradiates a laser to the sealing region SA between the lower substrate 101 and the upper substrate 130, the lower substrate 101 and the upper substrate 130 of the corresponding region may be bonded to each other while an interface between the lower substrate 101 and the upper substrate 130 is melted and then solidified. In this case, the laser may be a femtosecond (fs) laser, but the present disclosure is not limited thereto.

At (e.g., in or on) the display region DA and the touch pad region T_PA, the upper substrate 130 may have a shape that is recessed upward from the first sealing region SA1 and the second sealing region SA2. In other words, the lower surface of the upper substrate 130 at (e.g., in or on) the display region DA and the touch pad region T_PA may be recessed upward when compared to the lower surface of the upper substrate 130 at (e.g., in or on) the first sealing region SA1 and the second sealing region SA2. At (e.g., in or on) the display region DA and the touch pad region T_PA, the upper substrate 130 and the lower substrate 101 may be spaced apart from each other. In other words, the upper substrate 130 and the lower substrate 101 may have a separated space defined therebetween at (e.g., in or on) the display region DA and the touch pad region T_PA. The circuit driving layer 110 and the organic light-emitting element layer 120 may be disposed in the separated space.

The circuit driving layer 110 may be disposed in the separated space in which the upper substrate 130 and the lower substrate 101 are spaced apart from each other. The circuit driving layer 110 may be disposed on one surface of the lower substrate 101. The circuit driving layer 110 may be disposed at (e.g., in or on) the display region DA. The circuit driving layer 110 may include various suitable elements for providing a signal to the organic light-emitting element layer 120. The circuit driving layer 110 may include various suitable signal lines, for example, a scan line, a data line, a power line, and a light-emitting line. The circuit driving layer 110 may include a plurality of transistors and capacitors. The transistors may include a switching transistor and a driving transistor Qd provided for each pixel.

The organic light-emitting element layer 120 may be disposed on the circuit driving layer 110. The organic light-emitting element layer 120 may be disposed in the separated space in which the upper substrate 130 and the lower substrate 101 are spaced apart from each other. The organic light-emitting element layer 120 may be disposed at (e.g., in or on) the display region DA. Light produced from the organic light-emitting element layer 120 may be emitted to the outside through a display surface. For example, the light produced from the organic light-emitting element layer 120 may be emitted in an upper direction, for example, the third direction DR3.

The plurality of display signal pad terminals D_PE may be disposed on the display pad region D_PA of the lower substrate 101. The plurality of display signal pad terminals D_PE may be disposed outside the second sealing region SA2 in the second direction DR2. The plurality of display signal pad terminals D_PE may not overlap with the second sealing region SA2.

The touch electrode layer 140 and the polarizing layer POL may be disposed on the upper substrate 130. The touch electrode layer 140 may be disposed at (e.g., in or on) the display region DA of the upper substrate 130. As described above, because the sensing region TA mostly overlaps with the display region DA, it may be interpreted that the touch electrode layer 140 is disposed at (e.g., in or on) the sensing region TA of the upper substrate 130. The touch electrode layer 140 may include a plurality of touch electrodes, and a plurality of insulating layers. This will be described in more detail below.

The polarizing layer POL may be disposed on the touch electrode layer 140. The polarizing layer POL may be a polarizing film. The polarizing layer POL may be connected to the touch electrode layer 140 through a bonding layer. The polarizing layer POL may be disposed at (e.g., in or on) the display region DA and/or the sensing region TA. The polarizing layer POL may have a function of selectively transmitting and/or absorbing light (e.g., external light) that is incident from the outside of the display device 1 to prevent or reduce the reflection of external light. In an embodiment, the polarizing layer POL may be an absorbing polarizing film. The polarizing layer POL may include a flexible material, for example, such as polyvinyl alcohol (PVA).

However, the present disclosure is not limited thereto, and the polarizing layer POL may be a reflective polarizing film having a function of selectively transmitting and/or reflecting a polarization component of external light.

The touch signal pad terminal T_PE as described above may be disposed at (e.g., in or on) the touch pad region T_PA of the upper substrate 130. The touch signal pad terminal T_PE may be disposed at (e.g., in or on) the touch pad region T_PA. The touch signal pad terminal T_PE may not overlap with the second sealing region SA2 in the thickness direction. As described above, the touch printed circuit board 500 may be attached to the touch pad region T_PA. The touch signal pad terminal T_PE may be connected to the touch signal lead terminal T_LE of the touch printed circuit board 500.

In an embodiment, the touch signal pad terminal T_PE may include an opaque metal. Therefore, when the touch signal pad terminal T_PE is formed by including the opaque metal on the upper substrate 130, and then the laser sealing process of the upper substrate 130 and the lower substrate 101 is performed, the laser sealing may not be performed smoothly due to the touch signal pad terminal T_PE containing the opaque metal. For example, for the laser sealing process, the laser that is irradiated to the sealing region SA may be partially reflected by the touch signal pad terminal T_PE including the opaque metal, and thus, a sufficient amount of light from the laser may not reach the sealing region SA that is positioned below the touch signal pad terminal T_PE. Accordingly, a bonding failure between the upper substrate 130 and the lower substrate 101 may occur. However, according to an embodiment, when the touch signal pad terminal T_PE is disposed so as to not overlap with the sealing region SA, the bonding failure between the upper substrate 130 and the lower substrate 101 may be improved (e.g., may be prevented or reduced) even when the laser sealing process is performed after performing a process of disposing the touch signal pad terminal T_PE.

Hereinafter, the touch electrode layer 140 that is disposed on the upper substrate 130 will be described in more detail.

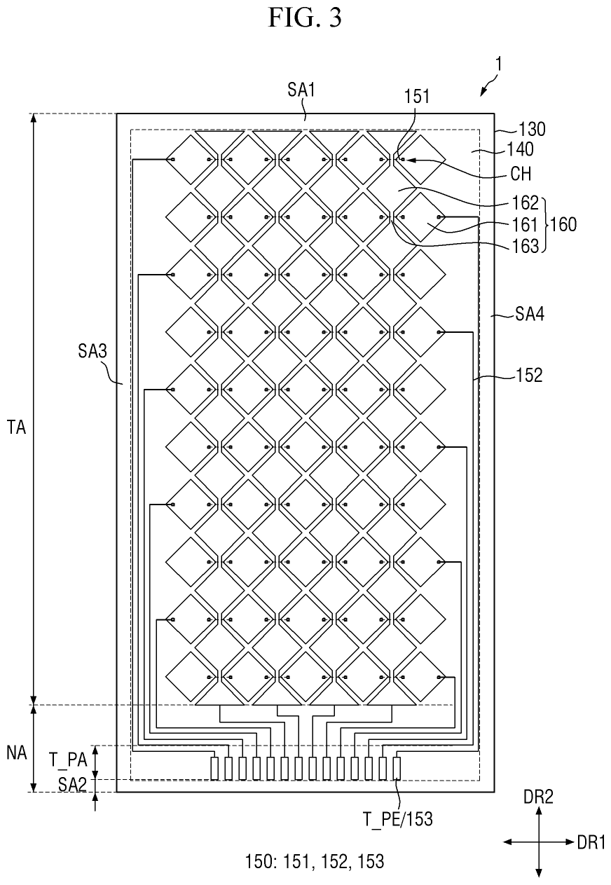

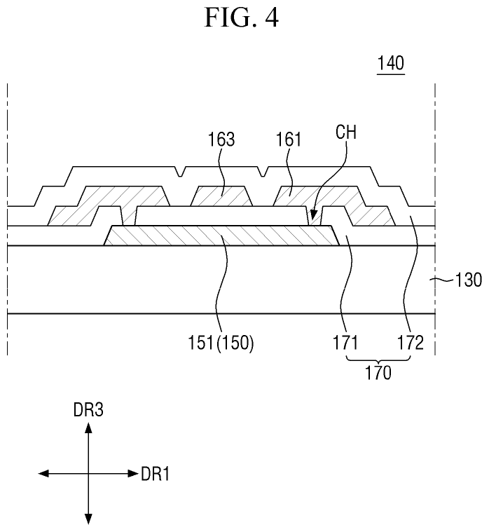

FIG. 3 is a planar layout view of an upper substrate according to an embodiment, and FIG. 4 is a cross-sectional view of a touch member of a sensing region according to an embodiment.

Referring to FIGS. 3 and 4, the upper substrate 130 includes the sensing region TA and the touch pad region T_PA as described above.

The sensing region TA of the upper substrate 130 includes a first wiring layer 150, a first insulating layer 171 disposed on the first wiring layer 150, a second wiring layer 160 disposed on the first insulating layer 171, and a second insulating layer 172 disposed on the second wiring layer 160.

The first wiring layer 150 is disposed on one surface of the upper substrate 130. The first wiring layer 150 includes a first connecting wiring 151. The first connecting wiring 151 of the first wiring layer 150 is disposed on the second wiring layer 160, which will be described in more detail below, and electrically connects adjacent ones of first touch electrodes 161 to each other.

The first wiring layer 150 may include a touch driving wiring 152, and a first pad electrode 153. The touch driving wiring 152 is connected to the first touch electrode 151 to extend toward the touch pad region T_PA, and forms the first pad electrode 153 at (e.g., in or on) the touch pad region T_PA. The first pad electrode 153 may have a shape that is more extended (e.g., that is slightly more extended) than that of the touch driving wiring 152, but the present disclosure is not limited thereto.

The first wiring layer 150 may be made of a conductive material. For example, the first wiring layer 150 may include a transparent conductive oxide such as indium tin oxide (ITO), indium zinc oxide (IZO), zinc oxide (ZnO), or indium tin zinc oxide (ITZO), an opaque conductive metal such as aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb, a conductive polymer such as PEDOT, metal nanowires, carbon nanotubes, graphene, or the like. In an embodiment, the first wiring layer 150 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, MoNb, or the like.

The first wiring layer 150 may include the touch driving wiring 152 and the first pad electrode 153. The touch driving wiring 152 is connected to the first touch electrode 151 to extend toward the touch pad region T_PA, and forms the first pad electrode 153 at (e.g., in or on) the touch pad region T_PA. The first pad electrode 153 may have a shape that is more extended (e.g., that is slightly more extended) than that of the touch driving wiring 152, but the present disclosure is not limited thereto.

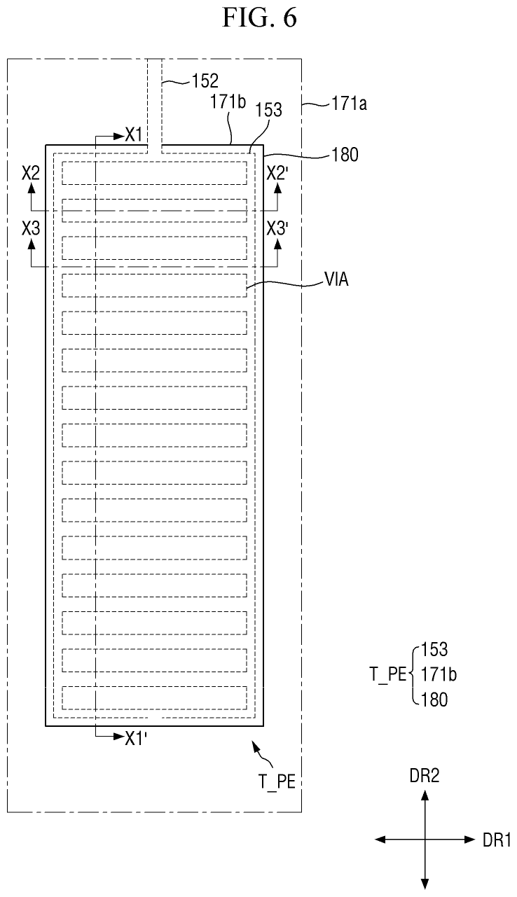

The first insulating layer 171 is disposed on the first wiring layer 150. The first insulating layer 171 covers and protects the first wiring layer 150. The first insulating layer 171 may be disposed over an entire surface of the upper substrate 130. The first insulating layer 171 may include a contact hole CH exposing the first connecting electrode 151. The first touch electrode 161, which will be described in more detail below, may be electrically connected to the first connecting electrode 151 exposed through the contact hole CH. The first insulating layer 171 may include a first sub insulating layer 171a disposed at (e.g., in or on) the sensing region TA, and a second sub insulating layer 171b disposed at (e.g., in or on) the touch pad region T_PA (e.g., see FIG. 6).

The second wiring layer 160 is disposed on one surface of the first insulating layer 171. The second wiring layer 160 includes the plurality of first touch electrodes 161, a plurality of second touch electrodes 162, and a plurality of second connecting electrodes 163. The first touch electrodes 161 and the second touch electrodes 162 may acquire location information of a point touched by a self-capacitance method and/or a mutual capacitance method.

The first touch electrodes 161 and the second touch electrodes 162 may be arranged in a matrix shape. The first touch electrodes 161 and the second touch electrodes 162 may have a rhombic shape, but the present disclosure is not limited thereto. The first touch electrodes 161 may be electrically connected to one another along a row direction (e.g., a short side direction or the first direction DR1), and the second touch electrodes 162 may be electrically connected to one another along a column direction (e.g., a long side direction or the second direction DR2). However, the present disclosure is not limited thereto, and the first touch electrodes 161 may be electrically connected to one another along the column direction, and the second touch electrodes 162 may be electrically connected to one another along the row direction. The first touch electrodes 161 and the second touch electrodes 162 are insulated from each other to be spaced apart (e.g., to be separated) from each other.

The second wiring layer 160 includes the second connecting wiring 163 for connecting the second touch electrodes 162 to one another. The second touch electrodes 162 that are adjacent to each other in the column direction are physically connected to each other through the second connecting wiring 163. A width of the second connecting wiring 163 may be smaller than that of each of the second touch electrodes 162. The second wiring layer 160 may be physically connected to the contact hole CH. When the contact hole CH is formed of (e.g., formed in) a material of the second wiring layer 160, a boundary between the contact hole CH and the first touch electrode 161 is not observed. However, the contact hole CH may be formed of (e.g., formed in) a material of the first wiring layer 150, or may be formed of (e.g., formed in) a material different from those of the first wiring layer 150 and the second wiring layer 160. In this case, boundaries of the contact hole CH and the first connecting electrode 151 and the first touch electrode 161 may be observed.

The first touch electrodes 161 that are adjacent to each other in the row direction in the second wiring layer 160 are physically spaced apart (e.g., are physically separated) from each other. The second connecting wiring 163 of the second wiring layer 160 electrically connects the neighboring (e.g., the adjacent ones of the) second touch electrodes 162 to each other. The width of the second connecting wiring 163 of the second wiring layer 160 may be smaller than that of each of the second touch electrodes 162.

The second wiring layer 160 may include one or more of the example materials of the first wiring layer 150 described above. In an embodiment, the second wiring layer 160 may include a transparent conductive oxide, for example, such as indium tin oxide (ITO), indium zinc oxide (IZO), zinc oxide (ZnO), or indium tin zinc oxide (ITZO).

The second insulating layer 172 is disposed on the second wiring layer 160. The second insulating layer 172 covers and protects the second wiring layer 160. The second insulating layer 172 may be disposed over an entire surface of the substrate 130.

Each of the first insulating layer 171 and the second insulating layer 172 may have a single layer structure or a multi-layered structure. In addition, each of the first insulating layer 171 and the second insulating layer 172 may include an inorganic material, an organic material, or a composite material. In an embodiment, at least one of the first insulating layer 171 and/or the second insulating layer 172 may include an inorganic film. The inorganic film may include at least one of aluminum oxide, titanium oxide, silicon oxide, silicon oxynitride, zirconium oxide, and/or hafnium oxide.

In another embodiment, at least one of the first insulating layer 171 and/or the second insulating layer 172 may include an organic film. The organic film may include at least one of acrylic resin, methacrylic resin, polyisoprene, vinyl resin, epoxy resin, urethane resin, cellulose resin, siloxane resin, polyimide resin, polyamide resin, and/or perylene resin.

The first pad electrode 153 may form the touch signal pad terminal T_PE at (e.g., in or on) the touch pad region T_PA. In an embodiment, the first pad electrode 153 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb. The metal materials described above may be metals having a relatively low resistance as compared with the material(s) included in the second wiring layer 160.

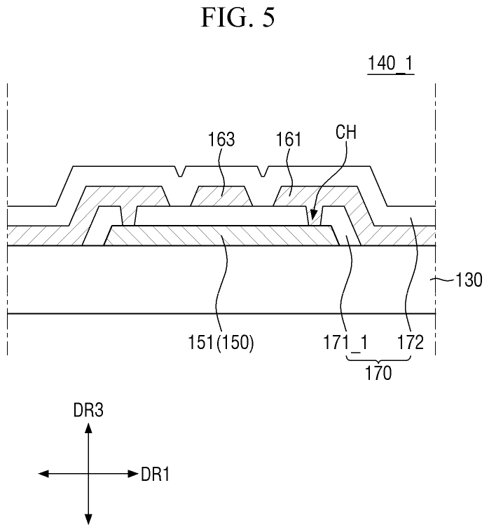

FIG. 5 is a cross-sectional view of a touch member of a sensing region according to a modified example. FIG. 5 illustrates that a first insulating layer 171_1 may not extend outside the second wiring layer 160 disposed thereon, and the second wiring layer 160 may extend outside the first insulating layer 171_1.

Hereinafter, the touch signal pad terminal T_PE will be described in more detail.

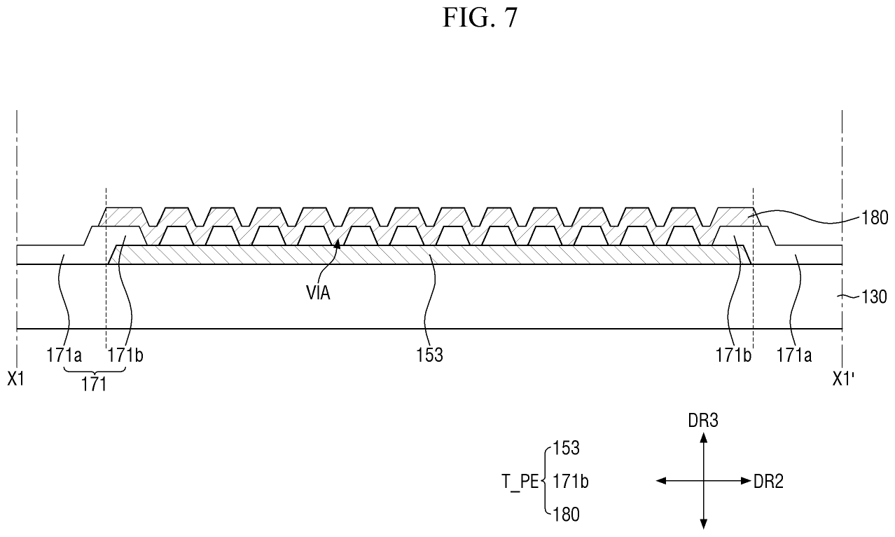

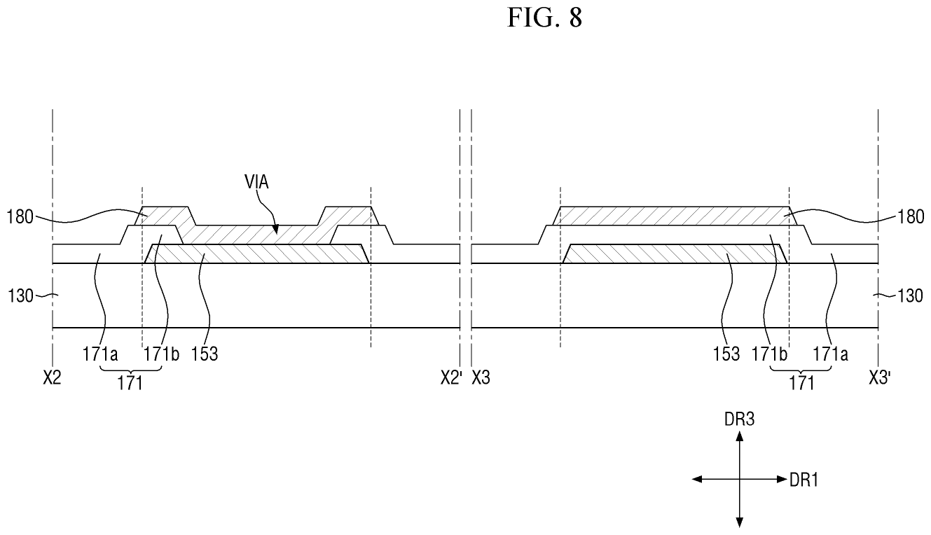

FIG. 6 is a planar layout view of a touch signal pad terminal according to an embodiment, FIG. 7 is a cross-sectional view taken along the line VII-VII′ of FIG. 6, and FIG. 8 is a cross-sectional view taken along the line VIII-VII′ and the line IX-IX′ of FIG. 6.

Referring to FIGS. 6 to 8, the touch signal pad terminal T_PE may include the first pad electrode 153, the second sub insulating layer 171b, and a second pad electrode 180. The first pad electrode 153 may be physically and electrically connected to the touch driving wiring 152. The first pad electrode 153 may have a rectangular shape having a long side edge and a short side edge. The second sub insulating layer 171b may be disposed on the first pad electrode 153, and may have the same or substantially the same shape as that of the first pad electrode 153 on a plane. A planar area of the second sub insulating layer 171b may be larger than a planar area of the first pad electrode 153. The second sub insulating layer 171b may be formed to extend outside the first pad electrode 153. The second sub insulating layer 171b may have a long side edge and a short side edge. The long side edge and the short side edge of the second sub insulating layer 171b may be extended in the second direction DR2 and the first direction DR1, respectively, like those of the first pad electrode 153. The long side edge and the short side edge of the second sub insulating layer 171b may be larger than the long side edge and the short side edge of the first pad electrode 153, respectively.

The first sub insulating layer 171a described above may be disposed outside the second sub insulating layer 171b. The first sub insulating layer 171a may surround (e.g., around a periphery of) both long side edges and both short side edges of the second sub insulating layer 171b.

The second sub insulating layer 171b may have a via hole VIA1. The via hole VIA1 may be formed in a thickness direction (e.g., the third direction DR3) at (e.g., in or on) a surface of the second sub insulating layer 171b to expose an upper surface of the first pad electrode 153.

The via hole VIA1 may extend in the first direction DR1, and may be spaced apart from adjacent via holes VIA1 in the second direction DR2. However, the present disclosure is not limited thereto, and the via hole VIA1 may extend in the second direction DR2, and may be spaced apart from adjacent via holes VIA1 in the first direction DR1. In FIG. 7, thirteen via holes VIA1 are illustrated for convenience, but the number of via holes VIA1 is not limited thereto.

The via hole VIA1 may have a long side and a short side on a plane. The via hole VIA1 may have the long side extending in the first direction DR1, and the short side extending in the second direction DR2. However, the present disclosure is not limited thereto, and the long side of the via hole VIA1 may extend in the second direction DR2, and the short side thereof may extend in the first direction DR1. The via hole VIA1 may be disposed inside (e.g., within) the first pad electrode 153 on a plane. The first pad electrode 153 may surround (e.g., around a periphery of) an insulating pattern.

The insulating pattern of the second sub insulating layer 171b may be formed between adjacent ones of the via holes VIA1. The insulating pattern may be disposed on the first pad electrode 153, and further, the insulating pattern may be disposed to extend outside the first pad electrode 153. The insulating pattern may have a shape surrounding (e.g., around a periphery of) the via hole VIA1 on the first pad electrode 153, and may have a shape surrounding (e.g., around a periphery of) the first pad electrode 153 on a plane on the outside of the first pad electrode 153. Thus, the insulating pattern may form an edge of the first pad electrode 153.

The second pad electrode 180 may be disposed on the first pad electrode 153 and the second sub insulating layer 171b. The second pad electrode 180 may protrude to the outside of the first pad electrode 153, and may extend therefrom. The second pad electrode 180 may cover the second sub insulating layer 171b. All side surfaces of the second pad electrode 180 may be aligned while overlapping with each side surface of the second sub insulating layer 171b in the thickness direction. In addition, the first sub insulating layer 171a on a plane may be disposed outside the second pad electrode 180 to surround (e.g., around a periphery of) all sides of the second pad electrode 180 from the outside. In other words, the first sub insulating layer 171a may form an edge of the second pad electrode 180. The second pad electrode 180 may cover upper and side surfaces of a plurality of insulating patterns of the second sub insulating layer 171b. The second pad electrode 180 may be disposed at (e.g., in or on) the via hole VIA1 disposed between the insulating patterns to cover the exposed first pad electrode 153. The second pad electrode 180 may be electrically connected to the first pad electrode 153 through the via hole VIA1.

The second pad electrode 180 may partially conformally reflect a lower step formed by the second sub insulating layer 171b. In other words, the second pad electrode 180 has a convex portion with a surface protruding in a region in which the insulating pattern is disposed, and a concave portion with a surface indented in a region in which the insulating pattern is not disposed, or in other words, in a region in which the via hole VIA1 is formed. In other words, the second sub insulating layer 171b having a step (e.g., a predetermined step) thereunder is disposed, so that the second pad electrode 180 may have a concave-convex shape on the surface thereof.

The second pad electrode 180 may be selected from among one or more of the example materials of the first pad electrode 150. In other words, in an embodiment, the second pad electrode 180 may include aluminum (Al), platinum (Pt), palladium (Pd), silver (Ag), magnesium (Mg), gold (Au), nickel (Ni), neodymium. (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb. These materials may be suitable to be ultrasonically bonded to the touch signal lead terminal T_LE disposed on the touch printed circuit board 500. This will be described in more detail below.

Referring again to FIG. 2, an ultrasonic apparatus 700 may vibrate the touch signal lead terminal T_LE in a vibration direction (e.g., a predetermined vibration direction) while vibrating in the vibration direction. However, in this case, the touch signal lead terminal T_LE may vibrate slightly in the vibration direction due to vibrations transmitted through the touch signal lead terminal T_LE, but a vibration amplitude thereof may be insignificant. In an embodiment, the vibration direction may be the second direction DR2. In other words, the vibration direction may be a direction in which the long sides of the touch signal lead terminal T_LE and the touch signal pad terminal T_PE extend.

When the touch signal lead terminal T_LE is ultrasonically vibrated on one surface of the touch signal pad terminal T_PE, a frictional force (e.g., a predetermined frictional force) is generated at an interface between one surface of the touch signal lead terminal T_LE and one surface of the touch signal pad terminal T_PE, and thus, frictional heat may be generated by the frictional force. When the frictional heat is sufficient to melt a material forming the touch signal lead terminal T_LE and the touch signal pad terminal T_PE, a first melting region T_LEb, which is adjacent to the touch signal pad terminal T_PE, of the touch signal lead terminal T_LE and a second melting region T_PEb, which is adjacent to the touch signal lead terminal T_LE, of the touch signal pad terminal T_PE may be melted. In other words, the touch signal lead terminal T_LE may include a first non-melting region T_LEa and the first melting region T_LEb. In addition, the touch signal pad terminal T_PE may include a second non-melting region T_PEa and the second melting region T_PEb.

The first non-melting region T_LEa may be a region including (e.g., including only) a material included in the touch signal lead terminal T_LE. The first melting region T_LEb may be a region including the material of the touch signal lead terminal T_LE, and further including a material included in the touch signal pad terminal T_PE.

The second non-melting region T_PEa may be a region including (e.g., including only) a material included in the touch signal pad terminal T_PE. The second melting region T_PEb may be a region including the material of the touch signal pad terminal T_PE, and further including a material included in the touch signal lead terminal T_LE.

The first melting region T_LEb is a region in which the material included in the touch signal pad terminal T_PE is diffused to mix the material of the touch signal lead terminal T_LE and the material of the touch signal pad terminal T_PE with each other, and the second melting region T_PEb may be a region in which the material included in the touch signal lead terminal T_LE is diffused to mix the material of the touch signal lead terminal T_LE and the material of the touch signal pad terminal T_PE with each other. For example, when the touch signal pad terminal T_PE includes silver (Ag), gold (Au), or copper (Cu), and the touch signal lead terminal T_LE includes Ti/Al/Ti, the first melting region T_LEb and the second melting region T_PEb may be a region in which Ti and/or Al of the touch signal lead terminal T_LE and silver (Ag), gold (Au), or copper (Cu) of the touch signal pad terminal T_PE are mixed with each other.

In the first melting region T_LEb and the second melting region T_PEb, the touch signal lead terminal T_LE and the touch signal pad terminal T_PE may be connected to each other while undergoing solidification.

An interface between the touch signal lead terminal T_LE and the touch signal pad terminal T_PE, or in other words, an interface between the first melting region T_LEb and the second melting region T_PEb, may have a non-flat shape.

As described above, the touch signal pad terminal T_PE may include the second pad electrode 180. The second pad electrode 180 may be opaque.

FIG. 9 is a perspective view illustrating a process of sealing an upper substrate and a lower substrate according to an embodiment. FIG. 9 is referenced to describe an effect of the display device 1 according to an embodiment.

As described above, bonding of the upper substrate 130 and the lower substrate 101 may be performed through a laser sealing process. The cell seal CS may bond the upper substrate 130 and the lower substrate 101 to each other, while a material such as a frit is melted and then solidified again. The laser sealing process may be performed through the laser sealing device 800. The laser sealing device 800 may move in one direction, and may irradiate the sealing region SA of the upper substrate 130 and the lower substrate 101 to bond the upper substrate 130 and the lower substrate 101 to each other.

In addition, the second pad electrode 180 of the touch signal pad terminal T_PE described above may include an opaque metal material, for example, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb, for ultrasonic bonding with the touch signal lead terminal T_LE.

However, when the opaque metal material is included in the second pad electrode 180 of the touch signal pad terminal T_PE, the laser irradiated from the laser sealing device 800 to the sealing region SA, for example, the second sealing region SA2, may not pass through the touch signal pad terminal T_PE, and may be partially reflected and/or absorbed by the second pad electrode 180 on the upper surface, and thus, only a small portion of the laser may reach the sealing region SA.

In this case, the frit that is interposed between the upper substrate 130 and the lower substrate 101 at (e.g., in or on) the sealing region SA may not be melted enough to sufficiently connection (e.g., bond, seal, or attach) the upper substrate 130 and the lower substrate 101 to each other, and accordingly, bonding properties of the upper substrate 130 and the lower substrate 101 may be significantly lowered.

However, in the display device 1 according to one or more embodiments, the touch pad region T_PA may not overlap with the sealing region SA of the display panel 100 in the thickness direction. In other words, a plurality of touch signal pad terminals T_PE may not overlap with the sealing region SA. Accordingly, the laser irradiated to the sealing region SA may directly pass through the upper substrate 130 without being partially reflected and/or absorbed by the touch signal pad terminal T_PE. As a result, the frit disposed at (e.g., in or on) the sealing region SA may be sufficiently melted. Therefore, even though an intensity or an irradiation time of the laser, which is a sealing light, is not increased, it may be possible to sufficiently bond the upper substrate 130 and the lower substrate 101 to each other.

Hereinafter, another example will be described. The same or substantially the same elements, layers, and configurations as those of the above-described embodiments is referred to by the same reference symbols in the following embodiments, and thus, redundant description thereof may be simplified or may not be repeated.

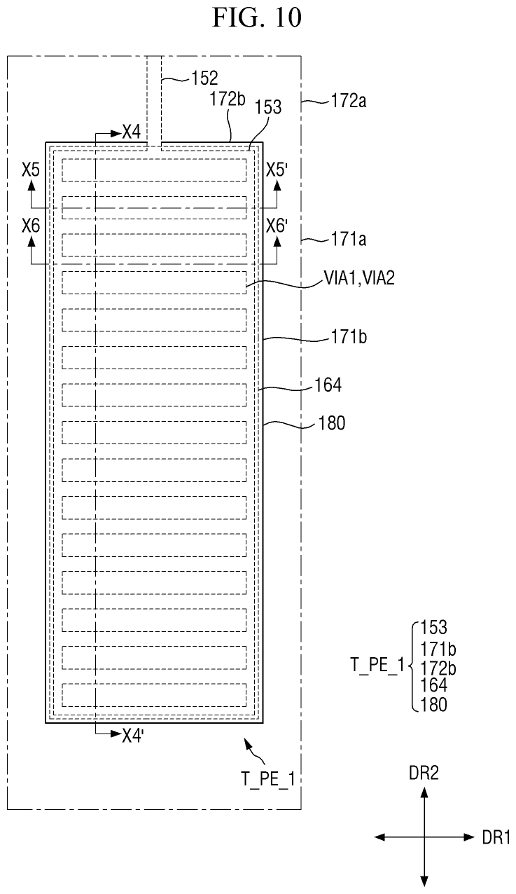

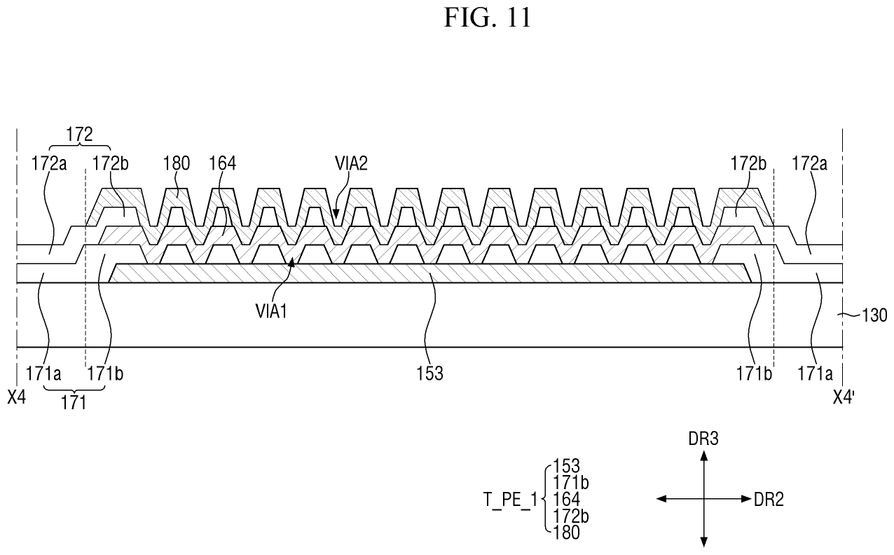

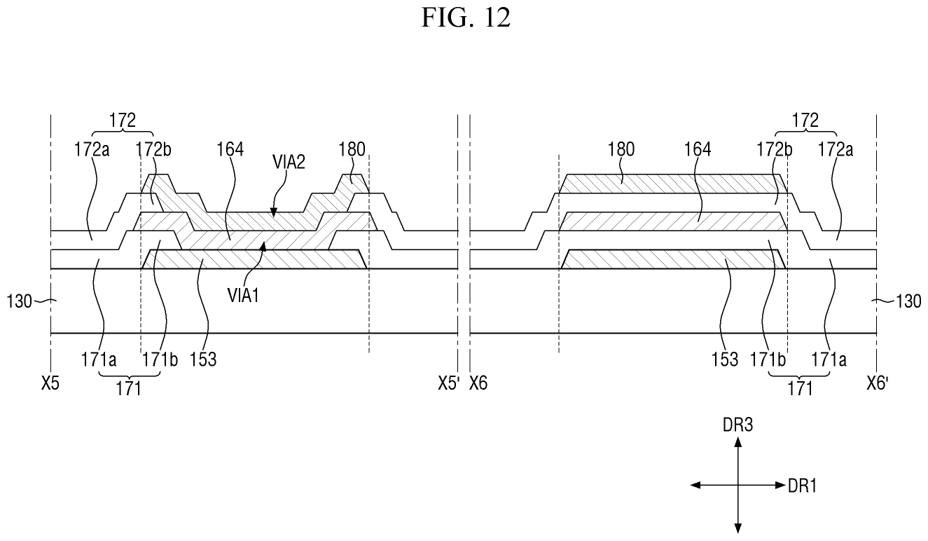

FIG. 10 is a planar layout view of a touch signal pad terminal according to another embodiment, FIG. 11 is a cross-sectional view taken along the line XI-XI′ of FIG. 10, and FIG. 12 is a cross-sectional view taken along the line XII-XII′ and the line XIII-XIII′ of FIG. 10.

Referring to FIGS. 10 to 12, a touch signal pad terminal T_PE_1 according to the present embodiment may be different from the touch signal pad terminal T_PE according to one or more embodiments of FIGS. 6 to 8, in that a third pad electrode 164 and a fourth sub insulating layer 172b may be further included in the touch signal pad terminal T_PE_1 of FIGS. 10 to 12.

In more detail, the touch signal pad terminal T_PE_1 may include the first pad electrode 153, the second sub insulating layer 171b disposed on the first pad electrode 153, the third pad electrode 164 disposed on the second sub insulating layer 171b, the fourth sub insulating layer 172b disposed on the third pad electrode 164, and the second pad electrode 180 disposed on the fourth sub insulating layer 172b.

The third pad electrode 164 may be disposed on one surface of the second sub insulating layer 171b, and may at least partially conformally reflect a lower step formed by a plurality of insulating patterns of the second sub insulating layer 171b. Accordingly, the third pad electrode 164 may have a surface concave-convex shape. The third pad electrode 164 may be electrically connected to the first pad electrode 153 through a first via hole VIA1 of the second sub insulating layer 171b.

The third pad electrode 164 may be disposed on the second wiring layer 160 of the sensing region TA. The third pad electrode 164 may be made of a material included in the second wiring layer 160. For example, the third pad electrode 164 may include a transparent conductive oxide such as indium tin oxide (ITO), indium zinc oxide (IZO), zinc oxide (ZnO), or indium tin zinc oxide (ITZO).

The third pad electrode 164 may be larger than the first pad electrode 153 on a plane, and smaller than the second pad electrode 180. The third pad electrode 164 may be disposed to extend outward from at least one side surface of the first pad electrode 153. The third pad electrode 164 may extend outward from all side surfaces of the first pad electrode 153. The second pad electrode 180 may be disposed to extend outward from at least one side surface of the third pad electrode 164. The second pad electrode 180 may extend outward from all side surfaces of the third pad electrode 164.

The fourth sub insulating layer 172b may be disposed on one surface of the third pad electrode 164. The fourth sub insulating layer 172b may have a second via hole VIA2 disposed between the plurality of insulating patterns and adjacent insulating patterns. The fourth sub insulating layer 172b may be disposed at (e.g., in or on) the same layer as that of the second insulating layer 172 of the sensing region TA. In other words, the second insulating layer 172 may include a third sub insulating layer 172a and the fourth sub insulating layer 172b.

The second pad electrode 180 may be electrically connected to the third pad electrode 164 through a plurality of second via holes VIA2 of the fourth sub insulating layer 172b. The second pad electrode 180 may have a concave-convex shape on the surface by reflecting at least partially conformally a step formed by the fourth sub insulating layer 172b.

Even in the present example, when an opaque metal material is included as the second pad electrode 180 of the touch signal pad terminal T_PE_1, a laser irradiated from the laser sealing device 800 to the sealing region SA, for example, to the second sealing region SA2, may not pass through the touch signal pad terminal T_PE_1, and may be partially reflected and/or absorbed by the second pad electrode 180 on the upper surface, and thus, only a small portion of the laser may reach the sealing region SA.

In this case, the frit interposed between the upper substrate 130 and the lower substrate 101 at (e.g., in or on) the sealing region SA may not be melted enough to connect the upper substrate 130 and the lower substrate 101 to each other, and accordingly, bonding properties of the upper substrate 130 and the lower substrate 101 may be significantly lowered.

However, the touch pad region T_PA according to the present embodiment may not overlap with the sealing region SA of the display panel 100 in the thickness direction. In other words, a plurality of touch signal pad terminals T_PE_1 may not overlap with the sealing region SA. Accordingly, the laser irradiated to the sealing region SA may directly pass through the upper substrate 130 without being partially reflected and/or absorbed by the touch signal pad terminal T_PE_1. As a result, the frit disposed at (e.g., in or on) the sealing region SA may be sufficiently melted. Therefore, even though an intensity or an irradiation time of the laser, which is a sealing light, is not increased, it may be possible to sufficiently bond the upper substrate 130 and the lower substrate 101 to each other.

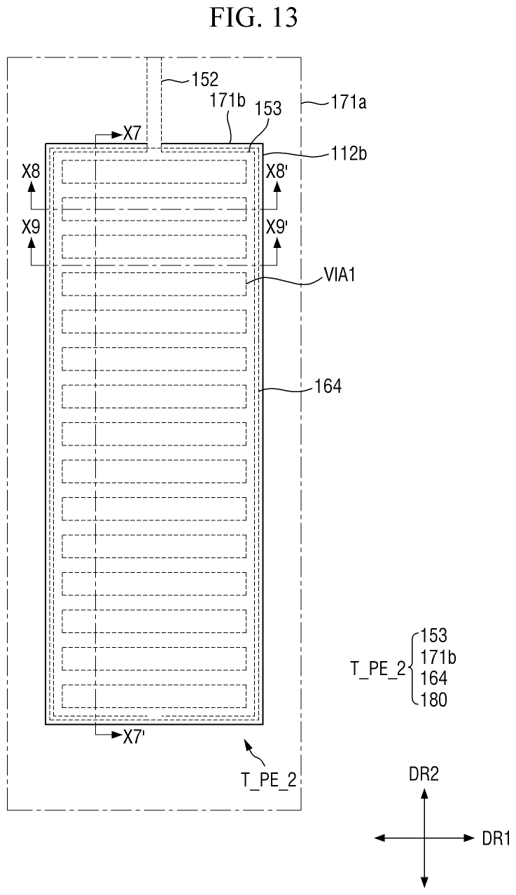

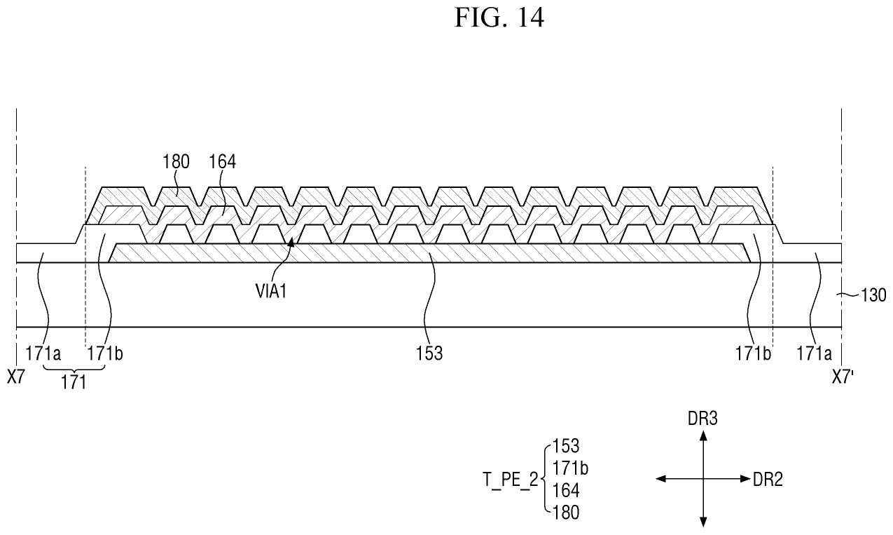

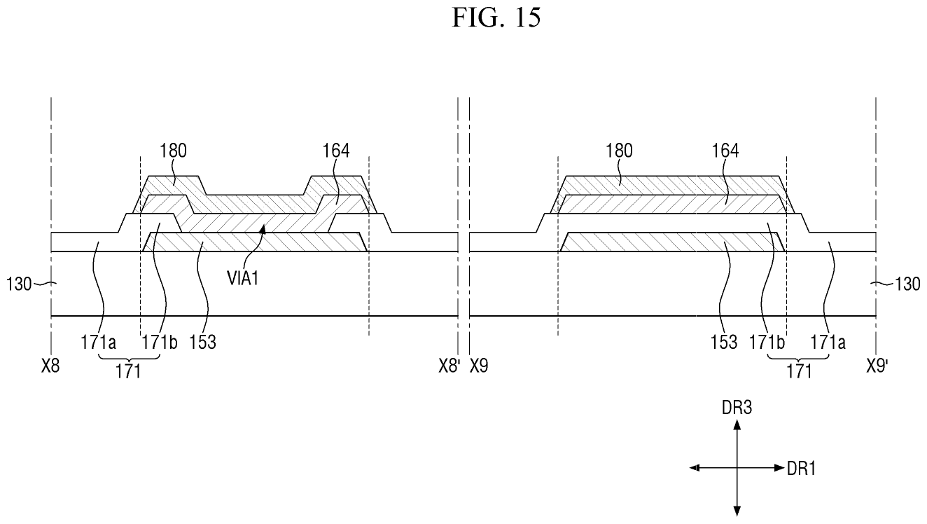

FIG. 13 is a planar layout view of a touch signal pad terminal according to another embodiment, FIG. 14 is a cross-sectional view taken along the line XIV-XIV′ of FIG. 13, and FIG. 15 is a cross-sectional view taken along the line XV-XV′ and the line XVI-XVI′ of FIG. 13.

Referring to FIGS. 13 to 15, a touch signal pad terminal T_PE_2 according to the present embodiment may be different from the touch signal pad terminal T_PE_1 according to one or more embodiments of FIGS. 10 to 12, in that the third pad electrode 164 may be omitted (e.g., may not be included) in the touch signal pad terminal T_PE_2 of FIGS. 13 to 15.

In more detail, the touch signal pad terminal T_PE_1 according to the present embodiment may include the first pad electrode 153, the second sub insulating layer 171b disposed on one surface of the first pad electrode 153, the third pad electrode 164 disposed on one surface of the second sub insulating layer 171b, and the second pad electrode 180 disposed on one surface of the third pad electrode 164.

Even in the present example, when an opaque metal material is included as the second pad electrode 180 of the touch signal pad terminal T_PE_2, a laser irradiated from the laser sealing device 800 to the sealing region SA, for example, to the second sealing region SA2, may not pass through the touch signal pad terminal T_PE_2, and may be partially reflected and/or absorbed by the second pad electrode 180 on the upper surface, and thus, only a small portion of the laser may reach the sealing region SA.

In this case, the frit interposed between the upper substrate 130 and the lower substrate 101 at (e.g., in or on) the sealing region SA may not be melted enough to connect the upper substrate 130 and the lower substrate 101 to each other, and accordingly, bonding properties of the upper substrate 130 and the lower substrate 101 may be significantly lowered.

However, the touch pad region T_PA according to the present embodiment may not overlap with the sealing region SA of the display panel 100 in the thickness direction. In other words, a plurality of touch signal pad terminals T_PE_2 may not overlap with the sealing region SA. Accordingly, the laser irradiated to the sealing region SA may directly pass through the upper substrate 130 without being partially reflected and/or absorbed by the touch signal pad terminal T_PE_2. As a result, it may be possible to sufficiently melt the frit disposed at (e.g., in or on) the sealing region SA. Therefore, even though an intensity or an irradiation time of the laser, which is a sealing light, is not increased, it may be possible to sufficiently bond the upper substrate 130 and the lower substrate 101 to each other.

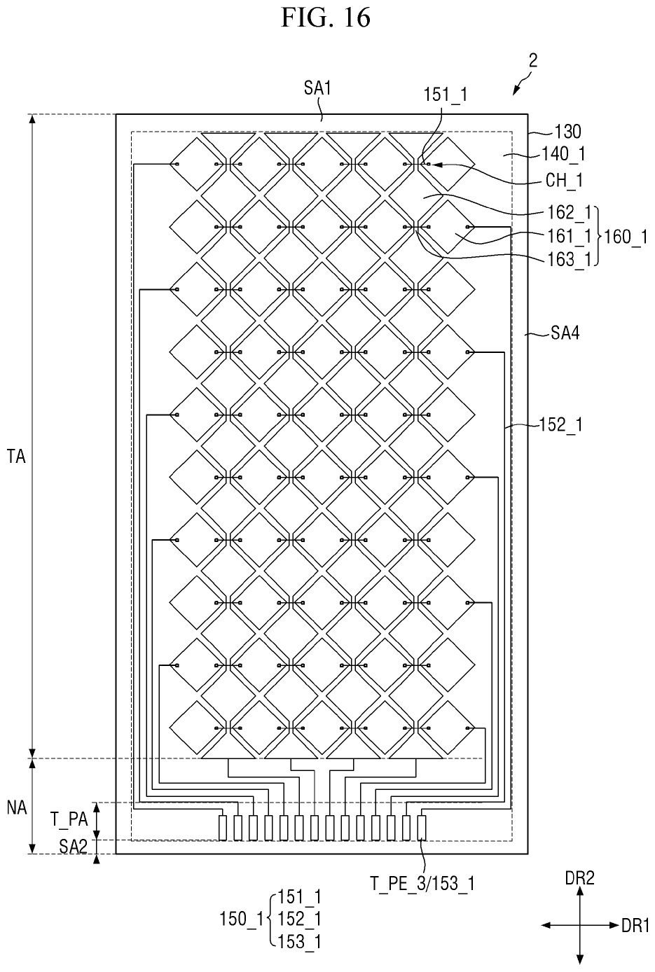

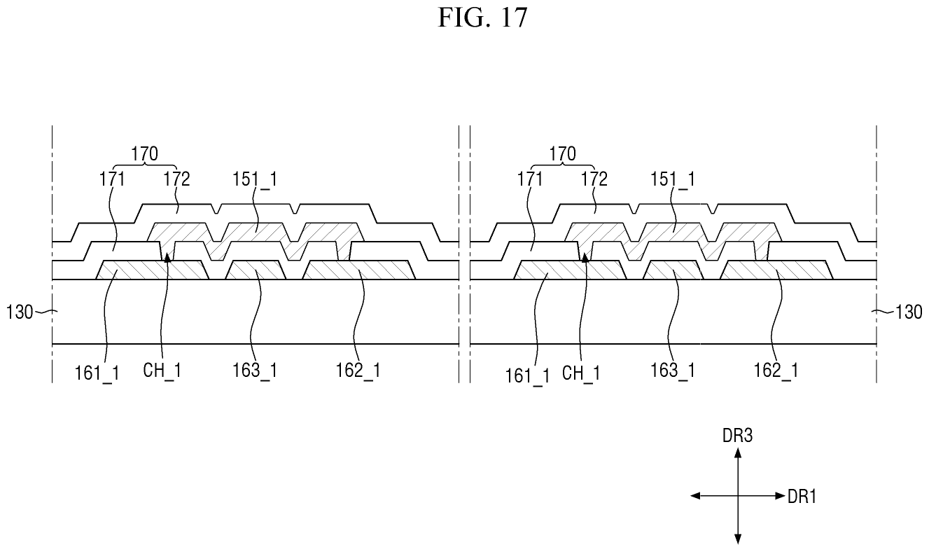

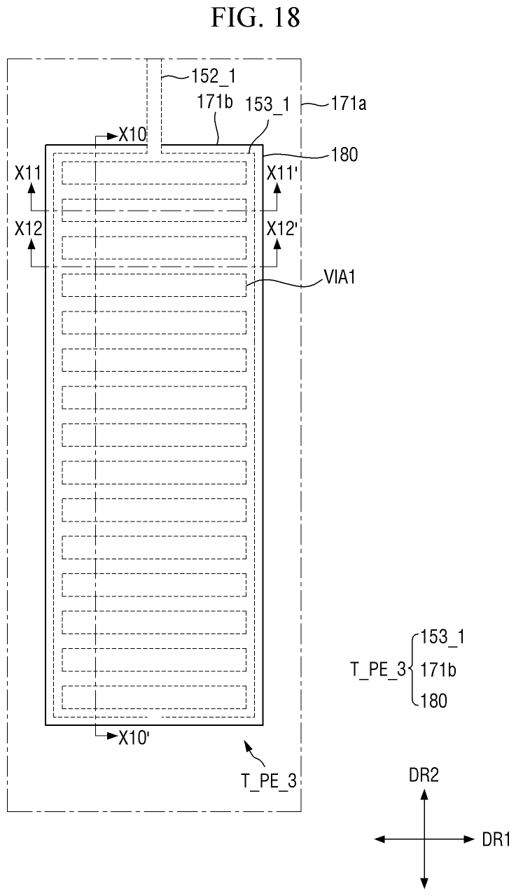

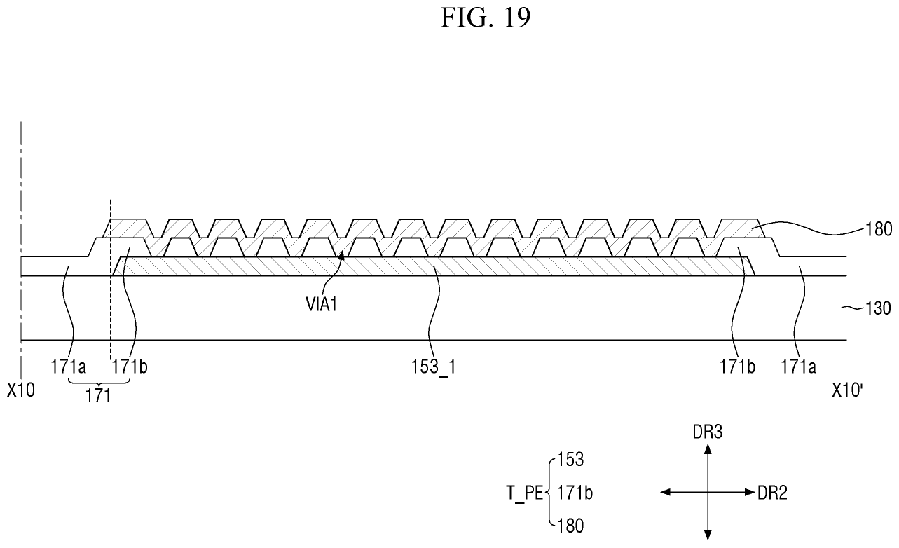

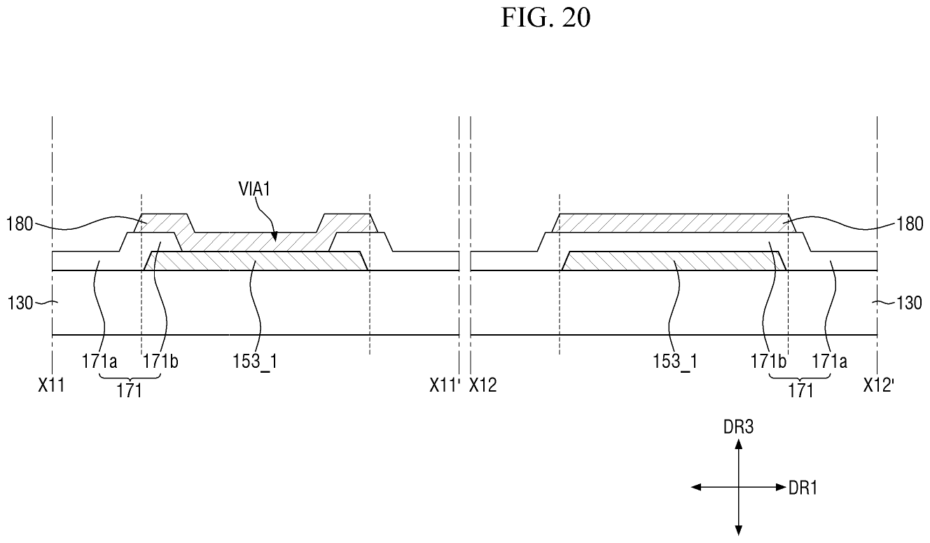

FIG. 16 is a planar layout view of an upper substrate according to another embodiment, FIG. 17 is a cross-sectional view of a touch member of a sensing region according to another embodiment, FIG. 18 is a planar layout view of a touch signal pad terminal according to another embodiment, FIG. 19 is a cross-sectional view taken along the line XIX-XIX′ of FIG. 18, and FIG. 20 is a cross-sectional view taken along the line XX-XX′ and the line XXI-XXI′ of FIG. 18.

FIGS. 16 to 20 illustrate that the wiring layer included in a touch element layer and a touch signal pad terminal may be variously modified.

Referring to FIGS. 16 to 20, a display device 2 according to the present embodiment may be different from the display device 1 according to one or more of the above-described embodiments, in that a touch element layer 140_1 and a touch signal pad terminal T_PE_3 are included in the display device 2.

In more detail, the touch element layer 140_1 according to the present embodiment may include a first wiring layer 160_1 and a second wiring layer 150_1. The first wiring layer 160_1 includes the same or substantially the same configuration and material as those of the second wiring layer 160 of the touch element layer 140 according to an embodiment, but the arrangement thereof may be different. The second wiring layer 150_1 includes the same or substantially the same configuration and material as those of the first wiring layer 150 of the touch element layer 140 according to an embodiment, but the arrangement thereof may be different. In more detail, the first wiring layer 160_1 may include a first touch electrode 161_1, a second touch electrode 162_1, and a second connection electrode 163_1. The second wiring layer 150_1 may include a first connection electrode 151_1, a touch driving wiring 152_1, and a first pad electrode 153_1. The first wiring layer 160_1 may be disposed on one surface of the upper substrate 130.

The first insulating layer 171 may be disposed on one surface of the first wiring layer 160_1. The second wiring layer 150_1 may be disposed on the first insulating layer 171. The first connection electrode 151_1 of the second wiring layer 150_1 may be electrically connected to the first wiring layer 160_1 through a contact hole CH_1. In other words, the first connection electrode 151_1 may be electrically connected to the first touch electrode 161_1 through the contact hole CH_1.

The touch signal pad terminal T_PE_3 may be different from the touch signal pad terminal T_PE according to an embodiment, in that the first pad electrode 153_1 may be included.

Even in the example, when an opaque metal material is included as the second pad electrode 180 of the touch signal pad terminal T_PE_3, a laser irradiated from the laser sealing device 800 to the sealing region SA, for example, to the second sealing region SA2, may not pass through the touch signal pad terminal T_PE_3, and may be partially reflected and/or absorbed by the second pad electrode 180 on the upper surface, and thus, only a small portion of the laser may reach the sealing region SA.

In this case, the frit interposed between the upper substrate 130 and the lower substrate 101 at (e.g., in or on) the sealing region SA may not be melted enough to connect the upper substrate 130 and the lower substrate 101 to each other, and accordingly, bonding properties of the upper substrate 130 and the lower substrate 101 may be significantly lowered.

However, the touch pad region T_PA according to the present embodiment may not overlap with the sealing region SA of the display panel 100 in the thickness direction. In other words, a plurality of touch signal pad terminals T_PE_3 may not overlap with the sealing region SA. Accordingly, the laser irradiated to the sealing region SA may directly pass through the upper substrate 130 without being partially reflected and/or absorbed by the touch signal pad terminal T_PE_3. As a result, it may be possible to sufficiently melt the frit disposed at (e.g., in or on) the sealing region SA. Therefore, even though an intensity or an irradiation time of the laser, which is a sealing light, is not increased, it may be possible to sufficiently bond the upper substrate 130 and the lower substrate 101 to each other.

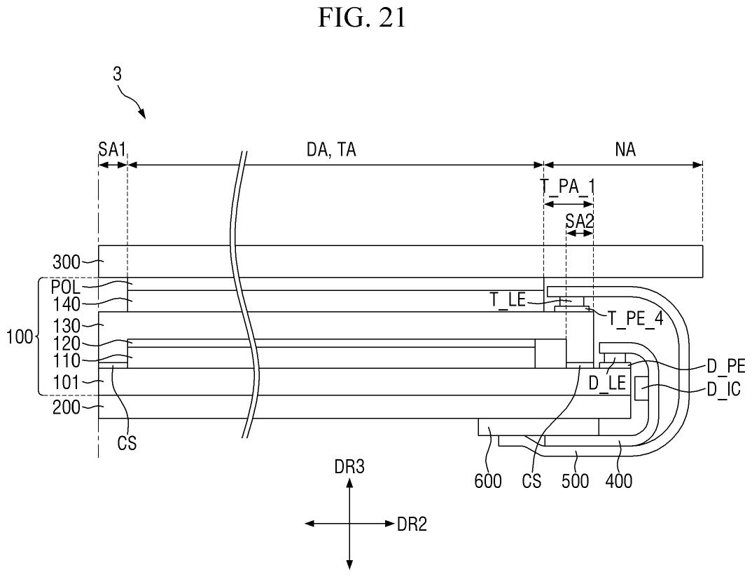

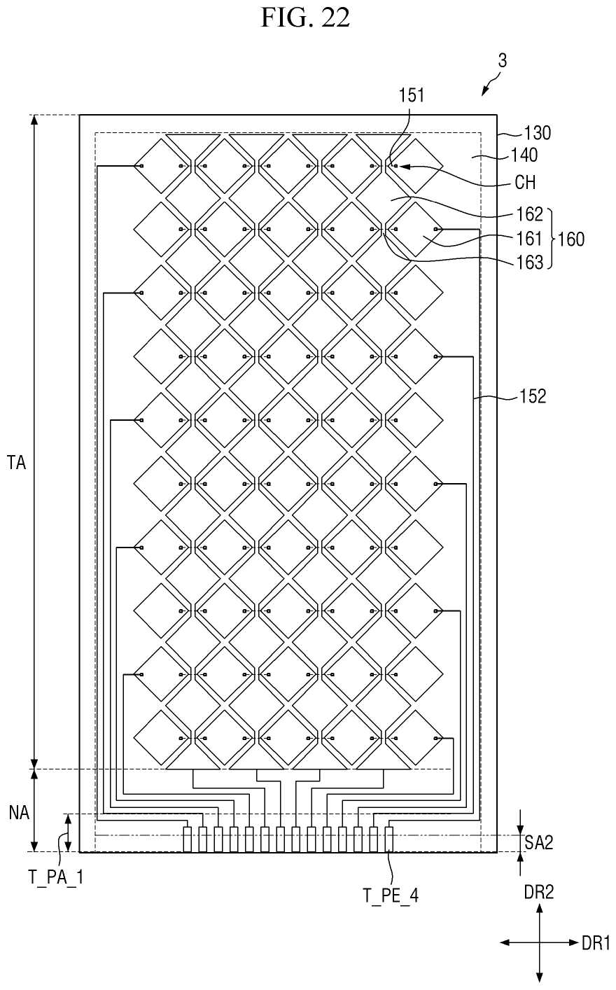

FIG. 21 is a cross-sectional view of a display device according to another embodiment, and FIG. 22 is a planar layout view of an upper substrate according to another embodiment. FIGS. 21 and 22 may be applied when a touch element layer 140 and a touch signal pad terminal T_PE_4 are formed on the upper substrate 130 after performing a sealing process of the upper substrate 130 and the lower substrate 101.

Referring to FIGS. 21 and 21, a display device 3 according to the present embodiment may be different from the device 1 according to one or more of the above-described embodiments, in that a touch pad region T_PA_1 and the second sealing region SA2 may partially overlap with each other in the thickness direction in the display device 3.

In more detail, one side of the touch pad region T_PA_1 that is adjacent to a non-display region NA may be aligned with one side of the second sealing region SA2 that is adjacent to the non-display region NA. The other side of the touch pad region T_PA_1 that is adjacent to a sensing region TA may be disposed to be further extended from the other side of the second sealing region SA2 that is adjacent to the sensing region TA.

The touch signal pad terminal T_PE_4 may be disposed at (e.g., in or on) the touch pad region T_PA_1. The touch signal pad terminal T_PE_4 may partially overlap with the second sealing region SA2.

The touch printed circuit board 500 may be attached to the touch pad region T_PA_1. The touch signal lead terminal T_LE disposed on the touch printed circuit board 500 may be connected to the touch signal pad terminal T_PE_4. The touch printed circuit board 500 may overlap with the second sealing region SA2 in the thickness direction.

As described above, the present embodiment may be applied when the touch element layer 140 and the touch signal pad terminal T_PE_4 are formed after performing the sealing process of the upper substrate 130 and the lower substrate 101. The second pad electrode 180 of the touch signal pad terminal T_PE_4 may include an opaque metal material for ultrasonic bonding with the touch signal lead terminal T_LE.

The touch element layer 140 and the touch signal pad terminal T_PE are formed on the upper substrate 130 through a suitable process, for example, such as deposition and patterning, and when the upper substrate 130 is bonded to the lower substrate 101 by a laser sealing process, as described above, a laser irradiated to the second sealing region SA2 may not pass through the touch signal pad terminal T_PE_3, and may be partially reflected and/or absorbed by the opaque second pad electrode 180 on the upper surface, and thus, only a small portion of the laser may reach the sealing region SA.

In this case, the frit interposed between the upper substrate 130 and the lower substrate 101 at (e.g., in or on) the sealing region SA may not be melted enough to connect the upper substrate 130 and the lower substrate 101 to each other, and accordingly, bonding properties of the upper substrate 130 and the lower substrate 101 may be significantly lowered.

However, in the display device 3 according to the present embodiment, after performing the laser sealing process of the upper substrate 130 and the lower substrate 101, the touch element layer 140 and the touch signal pad terminal T_PE_4 may be formed on one surface of the upper substrate 130 through a suitable process such as deposition and patterning. In this case, the touch signal pad terminal T_PE_4 may include an opaque metal material, for example, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb, and thus, the touch signal pad terminal T_PE_4 may be disposed to overlap with the sealing region SA because the touch signal pad terminal T_PE_4 is formed after the laser sealing process even though the laser transmittance thereof is low.

Accordingly, the sensing region TA and the display region DA of the display device 3 may be disposed to be further extended in one direction. In other words, because the touch signal pad terminal T_PE_4 may be disposed to overlap with the second sealing region SA2, an area of the sensing region TA may be relatively large (e.g., may be increased). In addition, the display region DA is a region in which light emitted from the organic light-emitting element layer 120 may be visually recognized from the outside, and the touch pad region T_PA_1 and the touch signal pad terminal T_PE_4 are disposed to overlap with the second sealing region SA2, and thus, the area may be relatively large (e.g., may be increased). As a result, a viewing region of the display may be increased, while reducing a bezel of the display device 3. Hereinafter, a method of manufacturing the display device 3 according to the present embodiment will be described.

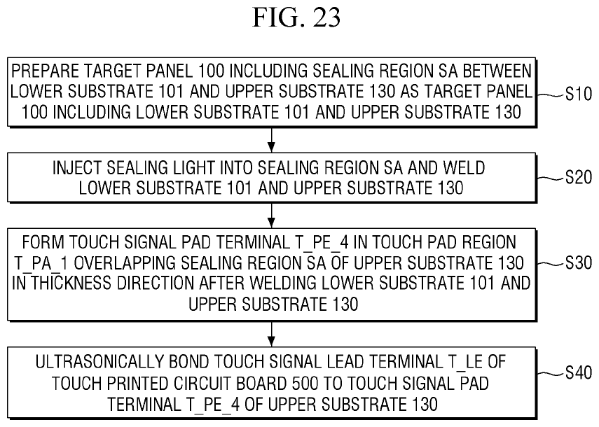

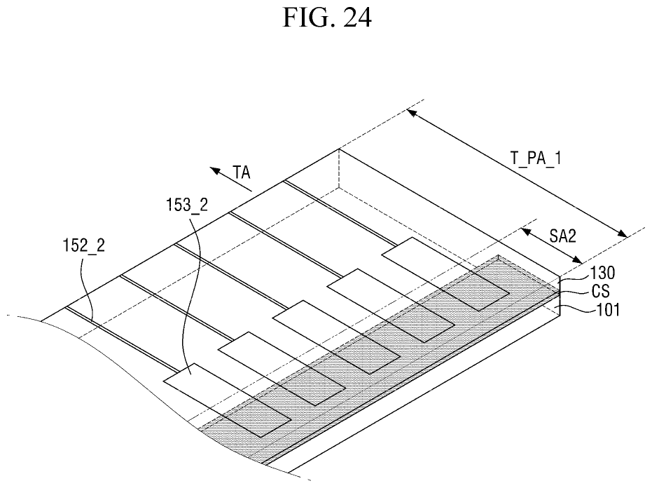

FIG. 23 is a flowchart illustrating a method of manufacturing a display device according to another embodiment, and FIGS. 24 to 26 are perspective views illustrating a process of forming a touch signal pad terminal.

Referring to FIGS. 23 to 26, the method of manufacturing a display device according to the present embodiment may include preparing a target panel 100 including a sealing region SA between a first substrate (e.g., a lower substrate) 101 and a second substrate (e.g., an upper substrate) 130 as the target panel 100 (S10), which includes the first substrate 101 and the second substrate 130. The method may further include injecting sealing light into the sealing region SA and welding the first substrate 101 and the second substrate 130 (S20) to each other. The method may further include forming a touch signal pad terminal T_PE_4 in a touch pad region T_PA_1 overlapping with the sealing region SA of the second substrate 130 in the thickness direction after welding the first substrate 101 and the second substrate 130 (S30) to each other. The method may further include ultrasonically bonding a touch signal lead terminal T_LE of a touch printed circuit board 500 to the touch signal pad terminal T_PE_4 of the second substrate 130 (S40).

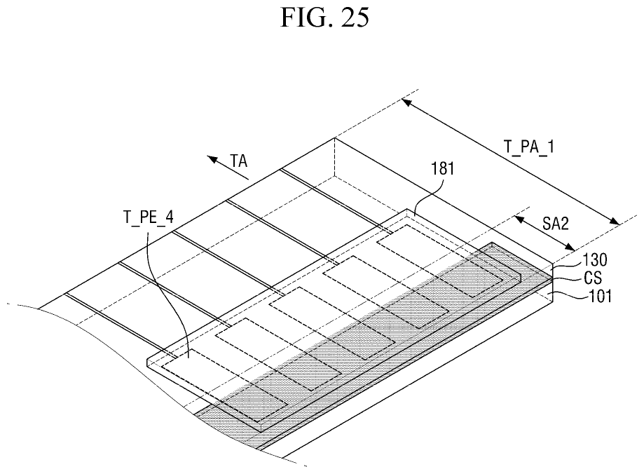

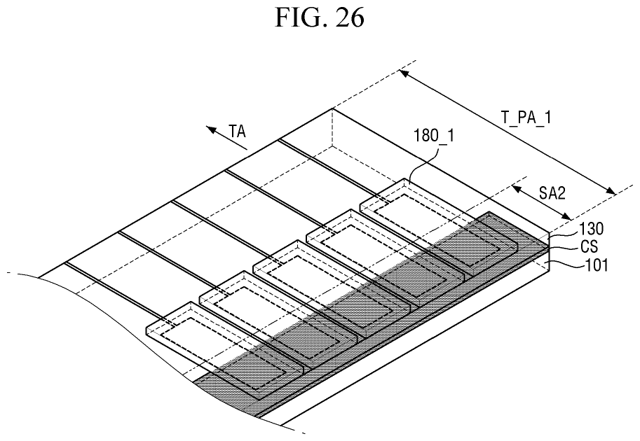

FIGS. 24 to 26 illustrate a process of forming a second pad electrode 180_1 on a first pad electrode 153_2. The second pad electrode 180_1 may be formed by a process of applying and curing a metal paste 181 on the first pad electrode 153_2 (e.g., see FIG. 25), and a patterning process of the metal paste 181 (e.g., see FIG. 26). Because various manufacturing methods related thereto are known to those having ordinary skill in the art, detailed descriptions thereof may not be repeated.

Although some example embodiments have been described, those skilled in the art will readily appreciate that various modifications are possible in the example embodiments without departing from the spirit and scope of the present disclosure. Therefore, it is to be understood that the foregoing is illustrative of various example embodiments and is not to be construed as limited to the specific example embodiments disclosed herein, and that various modifications to the disclosed example embodiments, as well as other example embodiments, are intended to be included within the spirit and scope of the present disclosure as defined in the appended claims, and their equivalents.

### DESCRIPTION OF REFERENCE SYMBOLS

100: Display panel
200: Panel lower sheet
300: Window
400: Display printed circuit board
500: Touch printed circuit board
600: Main circuit board
700: Ultrasonic bonding apparatus
800: Laser sealing device

1. A display device comprising:
a display region;
a non-display region surrounding the display region;
a first substrate;
a second substrate on the first substrate, and comprising a first surface facing the first substrate, and a second surface opposite to the first surface;
a touch electrode on the second surface of the second substrate at the display region;
a touch pad terminal on the second surface of the second substrate at the non-display region, and electrically connected to the touch electrode; and
a sealing member interposed between the first substrate and the second substrate, and connecting the first substrate and the second substrate to each other,
wherein the sealing member is at the non-display region, and
wherein the touch pad terminal is located more inward than the sealing member.

2. The display device of claim 1, wherein the touch pad terminal does not overlap with the sealing member.

3. The display device of claim 1, further comprising:
a display element,
wherein the first substrate comprises a first surface facing the second substrate, and a second surface opposite to the first surface of the first substrate, and
wherein the display element is located on the first surface of the first substrate.

4. The display device of claim 3, wherein the display element comprises an anode, a cathode, and an organic emission layer between the anode and the cathode.

5. The display device of claim 4, wherein the display element is sealed by the first substrate, the second substrate, and the sealing member.

6. The display device of claim 1, wherein the second substrate comprises glass or quartz.

7. The display device of claim 6, wherein the touch electrode is located directly on the second surface of the second substrate.

8. The display device of claim 1, wherein the sealing member comprises an optically transparent frit.

9. The display device of claim 1, wherein the touch electrode comprises a transparent electrode layer comprising a transparent conductive oxide.

10. The display device of claim 9, wherein the touch pad terminal comprises a first conductive layer comprising a transparent conductive oxide, and a second conductive layer on the first conductive layer and comprising an opaque metal.

11. The display device of claim 10, wherein the transparent electrode layer and the first conductive layer comprise the same material as each other.

12. The display device of claim 10, wherein the second conductive layer comprises at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb.

13. The display device of claim 1, further comprising: a circuit board attached onto the second surface of the second substrate.

14. The display device of claim 13, wherein the circuit board comprises a lead terminal connected to the touch pad terminal.

15. The display device of claim 14, wherein the touch pad terminal and the lead terminal are ultrasonically bonded to each other.

16. The display device of claim 13, wherein the first substrate extends from one end of the second substrate to the outside of the second substrate.

17. The display device of claim 16, wherein the circuit board is bent to surround a region of the first substrate extending from one end of the second substrate in a plan view, and one end of the circuit board is located below the second surface of the first substrate.

18. A display device comprises:
a display region;
a non-display region surrounding the display region;
a display substrate;
an encapsulation substrate on the display substrate, and comprising a first surface facing the display substrate, and a second surface opposite to the first surface;
a touch electrode on the second surface of the encapsulation substrate at the display region;
a touch pad terminal on the second surface of the encapsulation substrate at the non-display region, and electrically connected to the touch electrode;
a display element on the display region of the display substrate, and sealed by the display substrate, the sealing member, and the encapsulation substrate; and
a touch element on the encapsulation substrate, and overlapping with the display region of the display substrate,
wherein the touch pad terminal overlaps with a portion of a sealing region of the display substrate, and comprises a first pad conductive layer, and a second pad conductive layer on the first pad conductive layer, the second pad conductive layer comprising an opaque metal.

19. The display device of claim 18, wherein the touch electrode comprises a transparent electrode layer comprising a transparent conductive oxide.

20. The display device of claim 19, wherein the transparent electrode layer and the first pad conductive layer comprise the same material as each other.

21. The display device of claim 19, wherein the second pad conductive layer comprises at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), copper (Cu), molybdenum (Mo), Ti/Al/Ti, Mo/Al/Mo, Mo/AlGe/Mo, Ti/Cu, or MoNb.

22. The display device of claim 18, further comprising:
a display element,
wherein the display substrate comprises a first surface facing the encapsulation substrate, and a second surface opposite to the first surface of the first substrate, and
wherein the display element is located on the first surface of the display substrate.

23. The display device of claim 22, wherein the display element comprises an anode, a cathode, and an organic emission layer between the anode and the cathode.

24. The display device of claim 23, wherein the display element is sealed by the display substrate, the encapsulation substrate, and the sealing member.

25. The display device of claim 18, wherein the encapsulation substrate comprises glass or quartz, and the touch electrode is located directly on the second surface of the encapsulation substrate.

26. The display device of claim 18, wherein the sealing member comprises an optically transparent frit.

27. The display device of claim 18, further comprising:
a touch circuit board attached onto the second surface of the encapsulation substrate,
wherein the touch circuit board comprises a lead terminal connected to the touch pad terminal.

28. The display device of claim 27, wherein the touch pad terminal and the lead terminal are ultrasonically bonded to each other.

29. The display device of claim 27, wherein the display substrate extends from one end of the encapsulation substrate to the outside of the encapsulation substrate in a plan view.

30. The display device of claim 29, wherein the touch circuit board is bent to surround a region of the display substrate extending from the one end of the encapsulation substrate in the plan view, and
one end of the touch circuit board is located below the second surface of the display substrate.
